(19) United States
(12) Patent Application Publication
(10) Pub. No.: US 2009/0091242 A1
(43) Pub. Date: Apr. 9, 2009

(54) HOLE-INJECTING LAYER IN OLEDS

(76) Inventors: Liang-Sheng Liao, Rochester, NY (US); Kevin P. Klubek, West Henrietta, NY (US)

Correspondence Address: Frank Pincelli;Patent Legal Staff, Eastman Kodak Company, 343 State Street, Rochester, NY, 14650-2201, US

(21) Appl. No.: 11/867,707

(22) Filed: Oct. 5, 2007

(51) Int. Cl. H01L 51/52

(52) U.S. Cl. 313/504

(57) ABSTRACT

An OLED including an anode; a cathode; a hole-injecting layer disposed over the anode, wherein the hole-injecting layer includes a first organic material with a reduction potential greater than −0.1 V and a lesser amount by volume of a second material with an oxidation potential less than 0.7 V, and wherein the second material does not include metal complexes; a hole-transporting layer disposed over the hole-injecting layer; a light-emitting layer disposed between the hole-transporting layer and the cathode; and an electron-transporting layer disposed between the light-emitting layer and the cathode.

### CROSS REFERENCE TO RELATED APPLICATION

Reference is made to commonly assigned U.S. patent application Ser. No. 11/301,458 filed Dec. 13, 2005, by Kevin P. Klubek et al., entitled “Electroluminescent Device Containing An Anthracene Derivative”, the disclosure of which is herein incorporated by reference.

### FIELD OF INVENTION

The present invention relates to organic light-emitting devices (OLEDs) or organic electroluminescent (EL) devices having an improved hole-injecting layer.

### BACKGROUND OF THE INVENTION

Multiple-layered OLEDs or organic EL devices, as first described by Tang in commonly assigned U.S. Pat. No. 4,356,429, are used as color pixel components in OLED displays and as solid-state lighting sources. OLEDs are also useful for some other applications due to their low drive voltage, high luminance, wide viewing angle, fast signal response time, and simple fabrication process.

A typical OLED includes two electrodes and one organic EL unit disposed between the two electrodes. The organic EL unit commonly includes at least one organic hole-transporting layer (HTL) and one organic electron-transporting layer (ETL). One of the electrodes is the anode, which is capable of injecting positive charges (holes) into the HTL of the EL unit, and the other electrode is the cathode, which is capable of injecting negative charges (electrons) into the ETL of the EL unit. When the OLED is positively biased with certain electrical potential between the two electrodes, holes injected from the anode and electrons injected from the cathode can recombine and emit light from the ETL near and at the interface between the HTL and the ETL. Since at least one of the electrodes is optically transmissive, the emitted light can be seen through the transmissive electrode.

In order to improve device performance, numerous OLEDs with alternative layer structures have been disclosed. For example, there are three-layer OLEDs that contain an organic light-emitting layer (LEL) between the HTL and the ETL, such as that disclosed by Adachi et al., “Electroluminescence in Organic Films with Three-Layer Structure”, Japanese Journal of Applied Physics, 27, L269 (1988), and by Tang et al., “Electroluminescence of Doped Organic Thin Films”, Journal of Applied Physics, 65, 3610 (1989). The LEL commonly includes a host material doped with a guest material, otherwise known as a dopant. Further, there are other multilayer OLEDs that contain additional functional layers, such as a hole-injecting layer (HIL), an electron-injecting layer (EIL), an electron-blocking layer (EBL), or a hole-blocking layer (HBL).

In an OLED fabrication process, the anode is typically formed on the substrate during a process that is separate from the fabrication of the rest of the OLED. For example, a commonly used transparent anode, indium-tin-oxide (ITO) or indium zinc-oxide (IZO) is formed and patterned on a transparent substrate or on a thin film transistor (TFT) backplane by an ion sputtering technique. However, the as-prepared or clean ITO cannot be used as an effective anode because of its relatively low work function. The low work function anode will form a high barrier for holes to inject from the anode into the adjacent organic EL unit, resulting in high drive voltage and low operational lifetime. Therefore, the anode top surface typically needs to be modified. Prior art, such as that reported by Mason et al. in Journal of Applied Physics 86(3), 1688 (1999), indicate that the work function of an anode, such as ITO, is related to the oxygen content on the surface, and increasing the oxygen content on the anode surface will increase the work function of the anode. Thus, an anode can be modified by an oxygen treatment, such as oxygen plasma treatment or ultraviolet excited ozone exposure (or UV ozone treatment).

An OLED fabricated on an oxygen-treated anode has improved EL performance compared to that fabricated on an as-received anode. However, the improved EL performance is not effective enough for practical applications. In order to further improve the EL performance, an anode with or without oxygen treatment can be modified by a layer over the anode surface, known as an anode buffer layer, before an organic EL unit is formed on its surface. This anode buffer layer in contact with the anode top surface, such as a thin oxide layer as disclosed in U.S. Pat. No. 6,351,067, and a plasma-deposited fluorocarbon polymers (denoted as CFₓ) as disclosed in U.S. Pat. No. 6,208,075, can enhance the luminous efficiency and the operational lifetime of an OLED.

In addition to the anode surface modification, selecting a suitable HIL is also important to facilitate hole injection from the anode into the EL unit while maintaining a stable interface between the anode and the HIL or between an anode buffer layer and the HIL, thereby reducing the drive voltage of the OLEDs.

In prior art, the HIL is commonly formed using a hole-injecting material having its HOMO level close to the work function of the anode. As a result, there will either be no energy barrier or a low energy barrier for hole injection at the interface between the anode and the HIL. Commonly selected hole-injecting materials include porphyrinic compounds as described in U.S. Pat. No. 4,720,432 and some aromatic amines, for example, 4,4′,4″-tris[(3-ethylphenyl)phenylamino]triphenylamine (m-TDATA). Some aromatic tertiary amines are also used as hole-injecting materials. Alternative hole-injecting materials reportedly useful in OLEDs are described in EP 0 891 121 A1 and EP 1 029 909 A1. In addition, a p-type doped organic layer is also useful for the HIL as described in U.S. Pat. No. 6,423,429. The term “p-type doped organic layer” means that this layer has semiconducting properties after doping, and the electrical current through this layer is substantially carried by the holes. The conductivity is provided by the formation of a charge-transfer complex as a result of hole transfer from the dopant to the host material. However, the aforementioned HIL's described by the prior art (with its HOMO level close to the work function of the anode) are not stable. An OLED having this type of HIL usually has high voltage rise during operation, resulting in inferior performance.

It is known that the operational lifetime of an OLEDs is determined by luminance stability. Generally, the lifetime is defined as T₅₀ in hours, which is the duration from the starting time of testing to the time at which the luminance is reduced by 50% of its initial value at a given testing condition. Typically, most lifetime data for OLEDs are collected using a constant current mode, however the voltage rise during testing using this mode generally has minimal affect on device lifetime. For practical applications, however, most OLEDs are driven by a constant voltage mode, instead of a constant current mode. If an OLED has high voltage rise during operation using the constant voltage mode, the given current will likewise decrease because the constant voltage mode cannot provide increased voltage to keep the given current unchanged. This results in the luminance decreasing faster compared to what is observed for the constant current mode. The impact on OLEDs is that the lifetime will be much shorter for a device being operated using a constant voltage mode compared to a device that is tested using a constant current mode. Moreover, in most cases, there is a voltage limitation in the drive circuitry, especially for low cost drive circuitry and circuitry utilized for portable devices. Therefore, there is a limitation even when operating in a constant current mode. The voltage cannot continue increasing to maintain a given current value. If the current density cannot be maintained, luminance will likewise decrease, resulting in lower lifetimes. Therefore, in order to improve the lifetime of OLEDs, it is necessary to maintain a low voltage rise during operation.

Recently, it has been disclosed, by Son et al. in U.S. Pat. No. 6,720,573 and Liao et al. in US 2006/0240280 A1 and US 2006/0240281 A1, that organic materials having a low LUMO level (or low reduction potential), such as hexaazatriphenylene hexacarbonitrile (HAT-CN) and its derivatives, are useful as hole-injecting materials in OLEDs. The HIL is formed using a hole-injecting material having its LUMO level close to the work function of the anode. With this type of HIL in an OLED, the OLED can have not only low drive voltage, but also low voltage rise and improved lifetime during operation. However, there will still be a substantial voltage drop across the HIL if the HIL is a thick layer formed using this type of hole-injecting material. Moreover, this type of hole-injecting material usually has either a small molecular size or has a symmetrical molecular structure, both of which cause crystallization problems which results in deteriorated EL performance when forming a film having a thickness greater than 50 nm. This will limit the usefulness for this type of material.

Son et al. in U.S. Pat. No. 6,720,573 disclose their devices having a copper phthalocyanine (CuPc) doped HIL or having a 4,4″-bis[N-(1-naphtyl)-N-phenyl-amino]biphenyl (NPB) doped HIL. However, because of its strong optical absorption of red emission, CuPc doped HIL would cause reduced red emission in OLEDs, which is not be suitable for the application of full color displays. It was also found that the OLED with NPB-doped HIL would have increased drive voltage and reduced lifetime, which is also not suitable for its applications.

Therefore, there remains a need to further improve the HIL to enhance the EL performance of OLEDs.

### SUMMARY OF THE INVENTION

It is therefore an object of the present invention to improve the HIL in an OLED.

It is another object of the present invention to improve the EL performance of an OLED.

These objects are achieved by an OLED comprising:

a) an anode;

b) a cathode;

c) a hole-injecting layer disposed over the anode, wherein the hole-injecting layer includes a first organic material with a reduction potential greater than −0.1 V and a lesser amount by volume of a second material with an oxidation potential less than 0.7 V, and wherein the second material does not include metal complexes;

d) a hole-transporting layer disposed over the hole-injecting layer;

e) a light-emitting layer disposed between the hole-transporting layer and the cathode; and

f) an electron-transporting layer disposed between the light-emitting layer and the cathode.

The present invention makes use of a hole-injecting layer including at least two materials with specified reduction and oxidation potentials. It is an advantage of the present invention that an OLED having this doped hole-injecting layer can avoid crystallization, reduce optical absorption, have low drive voltage with low voltage rise during operation, while providing improved power efficiency and lifetime.

### BRIEF DESCRIPTION OF THE DRAWINGS

FIG. 1 shows a cross-sectional view of one embodiment of an OLED prepared in accordance with the present invention;

FIG. 2 shows a cross-sectional view of another embodiment of an OLED prepared in accordance with the present invention;

FIG. 3A is a graph showing the luminance vs. operational time of a group of OLEDs tested at room temperature and at an initial luminance of 10,000 cd/m²;

FIG. 3B is a graph showing the drive voltage vs. operational time of a group of OLEDs tested at room temperature and at an initial luminance of 10,000 cd/m²;

FIG. 4A is a graph showing the luminance vs. operational time of another group of OLEDs tested at room temperature and at 80 mA/cm²; and

FIG. 4B is a graph showing the drive voltage vs. operational time of another group of OLEDs tested at room temperature and at 80 mA/cm².

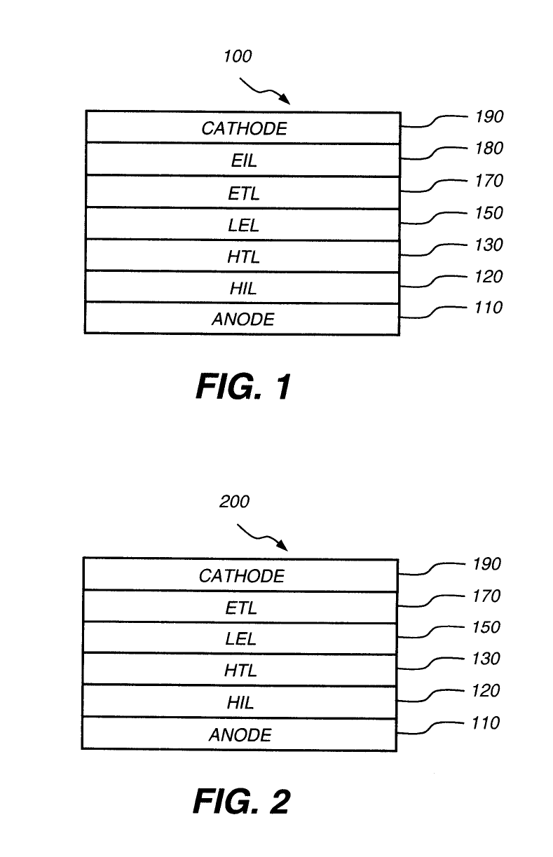

It will be understood that FIGS. 1-2 are not to scale since the individual layers are too thin and the thickness differences of various layers are too great to permit depiction to scale.

### DETAILED DESCRIPTION OF THE INVENTION

The present invention can be employed in many OLED configurations using small molecule materials, oligomeric materials, polymeric materials, or combinations thereof. These include from very simple structures having a single anode and cathode to more complex devices, such as passive matrix displays having orthogonal arrays of anodes and cathodes to form pixels, and active-matrix displays where each pixel is controlled independently, for example, with thin film transistors (TFTs). There are numerous configurations of the organic layers wherein the present invention is successfully practiced.

A typical structure according to the present invention and especially useful for a small molecule device is shown in FIG. 1. OLED 100 in FIG. 1 includes an anode 110, a HIL 120, a HTL 130, a LEL 150, an ETL 170, an EIL 180 and a cathode 190. OLED 100 can be operated by applying an electric potential produced by a voltage/current source between the pair of the electrodes, anode 110 and cathode 190. Shown in FIG. 2 is OLED 200, which is another embodiment of OLEDs prepared in accordance with the present invention. OLED 200 in FIG. 2 is the same as OLED 100 except that there is no EIL 180 in OLED 200.

In order to facilitate a detailed discussion on the aforementioned OLEDs, several terms are discussed as follows:

### Reduction Potential and Oxidation Potential

The term “reduction potential”, expressed in volts and abbreviated E^{red}, measures the affinity of a substance for an electron: the larger (more positive) the number, the greater the affinity. The reduction potential of a substance can be obtained by cyclic voltammetry (CV) and it is measured vs. a Saturated Calomel Electrode (SCE). The measurement of the reduction potential of a substance can be as follows: An electrochemical analyzer (for instance, a CHI660 electrochemical analyzer, made by CH Instruments, Inc., Austin, Tex.) is employed to carry out the electrochemical measurements. Both CV and Osteryoung square-wave voltammetry (SWV) can be used to characterize the redox properties of the substance. A glassy carbon (GC) disk electrode (A=0.071 cm²) is used as working electrode. The GC electrode is polished with 0.05 μm alumina slurry, followed by sonication cleaning in deionized water twice and rinsed with acetone between the two water cleanings. The electrode is finally cleaned and activated by electrochemical treatment prior to use. A platinum wire can be used as the counter electrode and the SCE is used as a quasi-reference electrode to complete a standard 3-electrode electrochemical cell. A mixture of acetonitrile and toluene (1:1 MeCN/toluene) or methylene chloride (MeCl₂) can be used as organic solvent systems. All solvents used are ultra low water grade (<10 ppm water). The supporting electrolyte, tetrabutylammonium tetrafluoroborate (TBAF) is recrystallized twice in isopropanol and dried under vacuum for three days. Ferrocene (Fc) can be used as an internal standard (E^{red}_{Fc}=0.50 V vs. SCE in 1:1 MeCN/toluene, E^{red}_{Fc}=0.55 V vs. SCE in MeCl₂, 0.1 M TBAF, both values referring to the reduction of the ferrocenium radical anion). The testing solution is purged with high purity nitrogen gas for approximately 15 minutes to remove oxygen and a nitrogen blanket is kept on the top of the solution during the course of the experiments. All measurements are performed at an ambient temperature of 25±1° C. If the compound of interest has insufficient solubility, other solvents can be selected and used by those skilled in the art. Alternatively, if a suitable solvent system cannot be identified, the electron accepting material can be deposited onto the electrode and the reduction potential of the modified electrode can be measured.

Similarly, the term “oxidation potential”, expressed in volts and abbreviated E^{ox}, measures the ability to lose an electron from a substance: the larger the value, the more difficult to lose an electron. The oxidation potential of a substance can also be obtained by using CV as discussed above.

### LUMO Energy and HOMO Energy

The electronic energy level of the Lowest Unoccupied Molecular Orbital (LUMO) of an organic material can be obtained based on the value of the reduction potential of the organic material. The relationship between LUMO energy and the E^{red} is:

LUMO(eV)=−4.8−[e×(E^{red} vs. SCE−E^{red}_{Fc} vs. SCE)] (eq. 1)

where, “e” is an unit of electron, e×1 V=1 eV=1.602×10⁻¹⁹ joules.

Similarly, the electronic energy level of the Highest Occupied Molecular Orbital (HOMO) of an organic material can be obtained based on the value of the oxidation potential of the organic material. The relationship between LUMO energy and the E^{ox} is:

HOMO(eV)=−4.8−[e×(E^{ox} vs. SCE−E^{red}_{Fc} vs. SCE)] (eq. 2)

For example, in 1:1 MeCN/toluene, if a material has an E^{red} vs. SCE=−2.0 V and an E^{ox} vs. SCE=1.0 V, the LUMO of the material is −2.3 eV, and the HOMO of the material is −5.3 eV (E^{red}_{Fc}=0.50 V vs. SCE in 1:1 MeCN/toluene).

There are other ways to measure the LUMO energy, such as by using inversed photoelectron spectroscopy (IPES). There are also other ways to measure the HOMO energy, such as by using ultraviolet photoelectron spectroscopy (UPS). LUMO energy is also commonly estimated based on the values of the measured HOMO energy minus the optical band gap for the material of interest.

### Substituent or Substituted

Unless otherwise specifically stated when a molecular structure is discussed, use of the term “substituted” or “substituent” means any group or atom other than hydrogen. Unless otherwise provided, when a group (including a compound or complex) containing a substitutable hydrogen is referred to, it is also intended to encompass not only the unsubstituted form, but also form further substituted derivatives with any substituent group or groups as herein mentioned, so long as the substituent does not destroy properties necessary for utility. Suitably, a substituent group can be halogen or can be bonded to the remainder of the molecule by an atom of carbon, silicon, oxygen, nitrogen, phosphorous, sulfur, selenium, or boron. The substituent can be, for example, halogen, such as chloro, bromo or fluoro; nitro; hydroxyl; cyano; carboxyl; or groups which can be further substituted, such as alkyl, including straight or branched chain or cyclic alkyl, such as methyl, trifluoromethyl, ethyl, t-butyl, 3-(2,4-di-t-pentylphenoxy) propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo-1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolylcarbonylamino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropyl-sulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbarnoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, and p-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which can be substituted and which contain a 3 to 7 membered heterocyclic ring composed of carbon atoms and at least one hetero atom selected from the group containing oxygen, nitrogen, sulfur, phosphorous, or boron, such as 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents can themselves be further substituted one or more times with the described substituent groups. The particular substituents used can be selected by those skilled in the art to attain the desired desirable properties for a specific application and can include, for example, electron-withdrawing groups, electron-donating groups, and steric groups. When a molecule can have two or more substituents, the substituents can be joined together to form a ring such as a fused ring unless otherwise provided. Generally, the above groups and substituents thereof can include those having up to 48 carbon atoms, typically 1 to 36 carbon atoms and usually less than 24 carbon atoms, but greater numbers are possible depending on the particular substituents selected.

It is well within the skill of the art to determine whether a particular group is electron donating or electron accepting. The most common measure of electron donating and accepting properties is in terms of Hammett σ values. Hydrogen has a Hammett σ value of zero, while electron donating groups have negative Hammett σ values and electron accepting groups have positive Hammett σ values. Lange's handbook of Chemistry, 12^{th} Ed., McGraw Hill, 1979, Table 3-12, pp. 3-134 to 3-138, here incorporated by reference, lists Hammett σ values for a large number of commonly encountered groups. Hammett σ values are assigned based on phenyl ring substitution, but they provide a practical guide for qualitatively selecting electron donating and accepting groups.

Suitable electron donating groups can be selected from —R′, —OR′, and —NR′(R″) where R′ is a hydrocarbon containing up to 6 carbon atoms and R″ is hydrogen or R′. Specific examples of electron donating groups include methyl, ethyl, phenyl, methoxy, ethoxy, phenoxy, —N(CH₃)₂, —N(CH₂CH₃)₂, —NHCH₃, —N(C₆H₅)₂, —N(CH₃)(C₆H₅), and —NHC₆H₅.

Suitable electron accepting groups can be selected from the group containing cyano, α-haloalkyl, α-haloalkoxy, amido, sulfonyl, carbonyl, carbonyloxy and oxycarbonyl substituents containing up to 10 carbon atoms. Specific examples include —CN, —F, —CF₃, —OCF₃, —CONHC₆H₅, —SO₂C₆H₅, —COC₆H₅, —CO₂C₆H₅, and —OCOC₆H₅.

The aforementioned terms will be frequently used in the following discussions. The following is the description of the layers, material selection, and fabrication process for the OLED embodiments shown in FIGS. 1-2.

### Anode 110

When the desired EL emission is viewed through the anode, anode 1 10 should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode 110. For applications where EL emission is viewed only through the cathode 190, the transmissive characteristics of the anode 110 are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable way such as evaporation, sputtering, chemical vapor deposition, or electrochemical process. Anodes can be patterned using well-known photolithographic processes. Optionally, anodes can be polished prior to application of other layers to reduce surface roughness so as to minimize short circuits or enhance reflectivity.

### Hole-Injecting Layer (HIL) 120

Unlike the prior art, HIL 120 in the OLEDs of the present invention includes a first organic material in greater molar amounts and a second material in lesser molar amounts, wherein the first organic material has a reduction potential greater than −0.1 V vs. SCE, preferably, greater than 0.5 V vs. SCE, and wherein the second material has an oxidation potential less than 0.8 V vs. SCE, preferably, less than 0.7 V vs. SCE. The first compound is different than the second compound.

By “electron-accepting” it is meant that the organic material has the capability or tendency to accept at least some electronic charge from other types of material that it is adjacent to. An electron-accepting material is also an oxidizing agent. By “electron-donating” it is meant that the organic material has the capability or tendency to donate at least some electronic charge to other types of material that it is adjacent to. An electron-donating material is also a reducing agent.

The first material(s) in HIL 120 in the present invention can be selected from several types of organic materials having a reduction potential greater than −0.1 V vs. SCE.

An organic material for use as a first material in the HIL 120 can be a chemical compound of Formula I

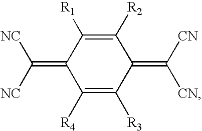

wherein R₁-R₄ represent hydrogen, fluorine, or substituents independently selected from the group including halo, nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, and substituted or unsubstituted alkyl, where R and R′ include substituted or unsubstituted alkyl or aryl; or wherein R₁ and R₂, or R₃ and R₄, combine to form a ring structure including an aromatic ring, a heteroaromatic ring, or a nonaromatic ring, and each ring is substituted or unsubstituted.

Specifically, the organic material for use as a first material in the HIL 120 can be a chemical compound of Formula Ia (2,3,5,6-tetrafluoro-7,7,8,8-tetracyano-quinodimethane [F₄-TCNQ])

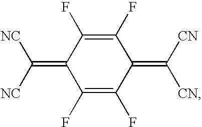

or can be a chemical compound of Formula Ib

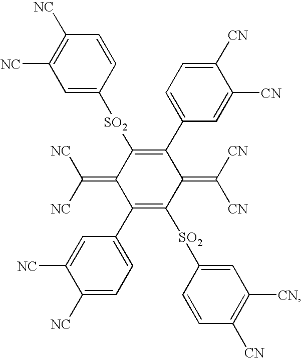

or can be a chemical compound of Formula Ic

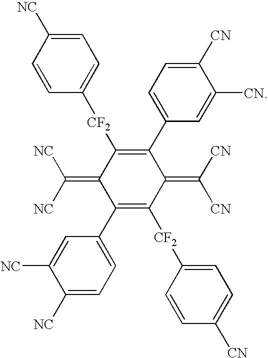

The organic material for use as the first material in the HIL 120 can also be a chemical compound of Formula IIa

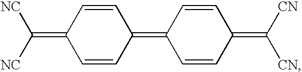

or can be a chemical compound of Formula IIb

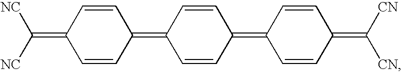

or can be a chemical compound of Formula IIc

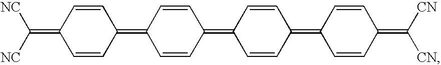

or can be a chemical compound of Formula IId

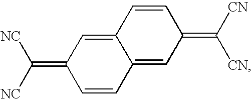

or can be a chemical compound of Formula IIe

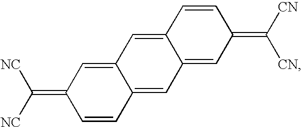

or can be a chemical compound of Formula IIf

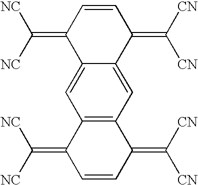

or a derivative of any of these compounds resulting from replacement of one or more hydrogen atoms by substituents including of halo, nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, and substituted or unsubstituted alkyl, where R and R′ include substituted or unsubstituted alkyl or aryl; or wherein two or more substituents combine form a ring structure including an aromatic ring, a heteroaromatic ring, or a nonaromatic ring, and each ring is substituted or unsubstituted.

The organic material for use as a first material in the HIL 120 can be a chemical compound of Formula III

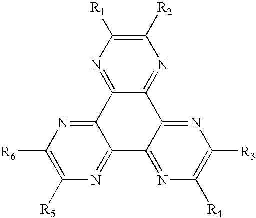

wherein R₁-R₆ represent hydrogen or a substituent independently selected from the group including halo, nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, and substituted or unsubstituted alkyl, where R and R′ include substituted or unsubstituted alkyl or aryl; or wherein R₁ and R₂, R₃ and R₄, or R₅ and R₆, combine form a ring structure including an aromatic ring, a heteroaromatic ring, or a nonaromatic ring, and each ring is substituted or unsubstituted.

Specifically, the organic material for use as a first material in the HIL 120 can be a chemical compound of Formula IIIa (hexaazatriphenylene hexacarbonitrile) (HAT-CN)

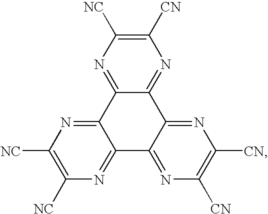

or can be a chemical compound of Formula IIIb

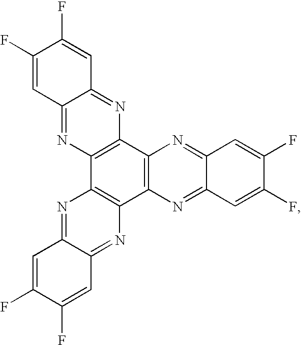

or can be a chemical compound of Formula IIIc

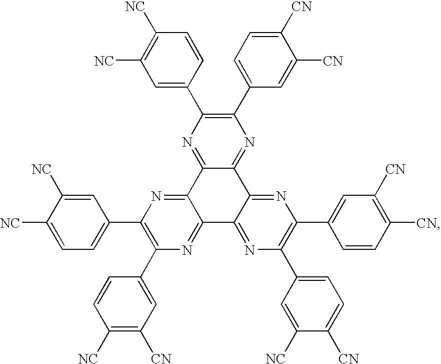

or can be a chemical compound of Formula IIId

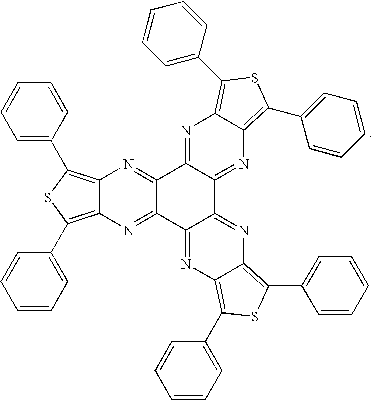

It should be noted that in addition to the aforementioned types of materials, other materials useful as the first materials in the HIL 120 can be selected from any materials having the reduction potential greater than −0.1 V. vs. SCE except metal complexes. Metal complexes as the first materials because the metal complexes can cause severe optical absorption resulting in reduced light output. Herein the metal complexes include transitional metal complexes having organic ligands and organometallic compounds.

The reduction potentials of some first materials are listed in Table 1:

TABLE 1
Reduction Potentials

| | Reduction Potential |
|---|---|
| Compound | (vs. SCE, V) |
| F₄-TCNQ | 0.64 |
| HAT-CN | −0.08 |

The second material in HIL 120 in the present invention can be selected from several types of organic materials having an oxidation potential less than 0.7 V vs. SCE. For example, a 2,6-diamino-substituted anthracene compound having an oxidation potential of less than 0.7V vs. SCE can be a suitable material for use as a second material in the HIL 120.

The organic material for use as a second material in the HIL 120 can be the 2,6-diamino-substituted anthracene compound represented by Formula IV

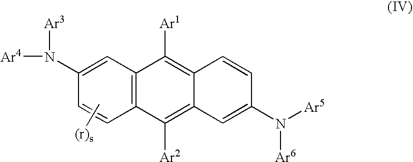

In Formula IV, each Ar³-Ar⁶ can be the same or different and each represents an independently selected aromatic group, such as a phenyl group, a tolyl group, or a naphthyl group. Any of Ar³-Ar⁶ on the same nitrogen can be further linked together to form a ring; for example two adjacent Ar³-Ar⁶ groups can combine to form a five, six or seven member ring.

Ar¹ and Ar² can be the same or different and each represents an independently selected aromatic group, such as a phenyl group, a tolyl group, or a naphthyl group. Ar¹ and Ar² can also represent N(Ar⁷)(Ar⁷), wherein each Ar⁷ can be the same or different and each represents an independently selected aromatic group.

In one suitable embodiment, Ar¹ and Ar² do not contain an aromatic amine. In another embodiment, Ar⁷ does not include an aromatic amine. In a further desirable embodiment, each Ar¹ and each Ar² represent an independently selected aryl group.

r represents an independently selected substituent, such as a methyl group or a phenyl group. Two adjacent r groups can combine to form a fused ring, such as a fused benzene ring group. In Formula IV, s is 0-3. In one suitable embodiment, s is 0.

Illustrative examples of compounds of Formula IV useful in the present invention are listed below.

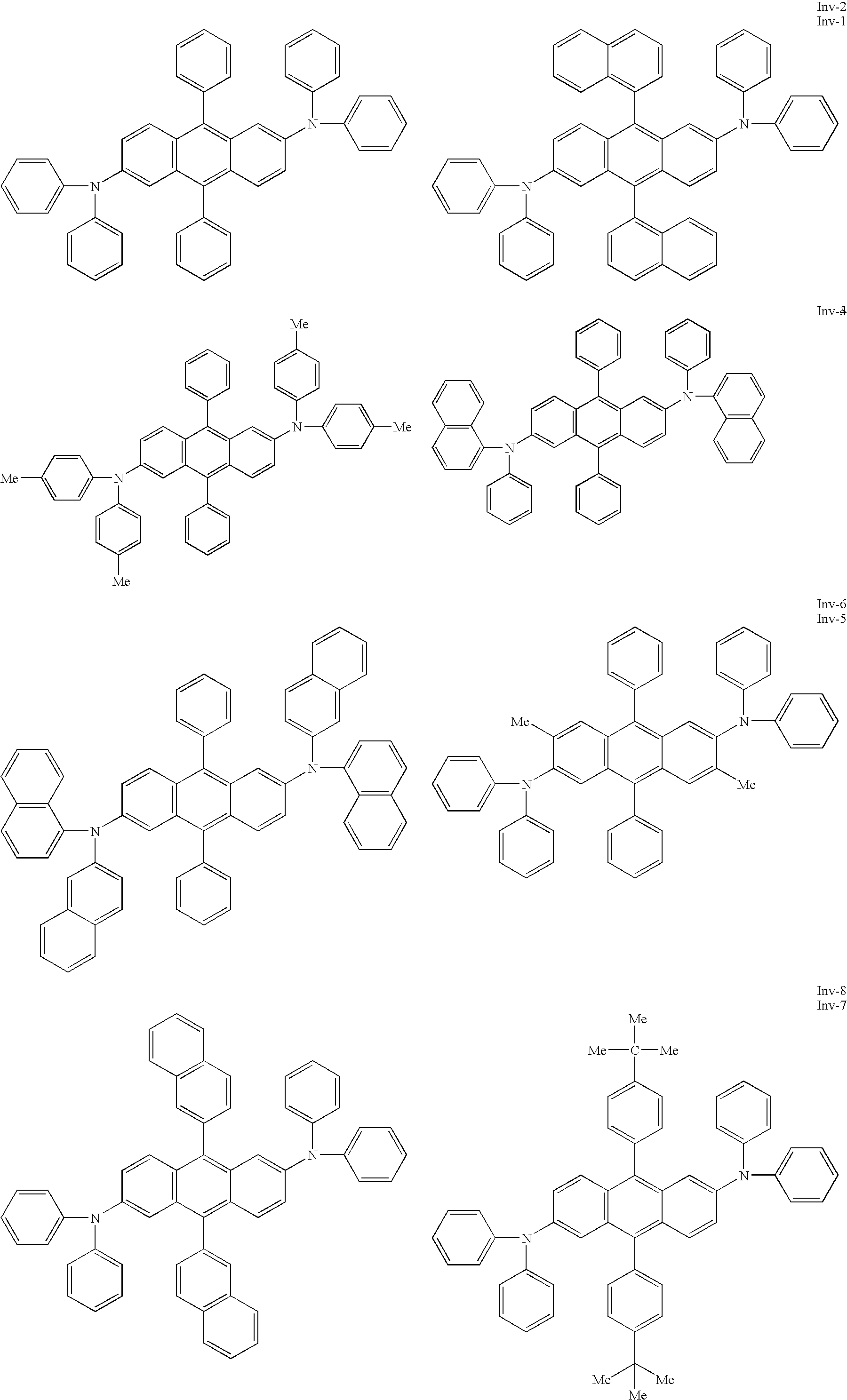

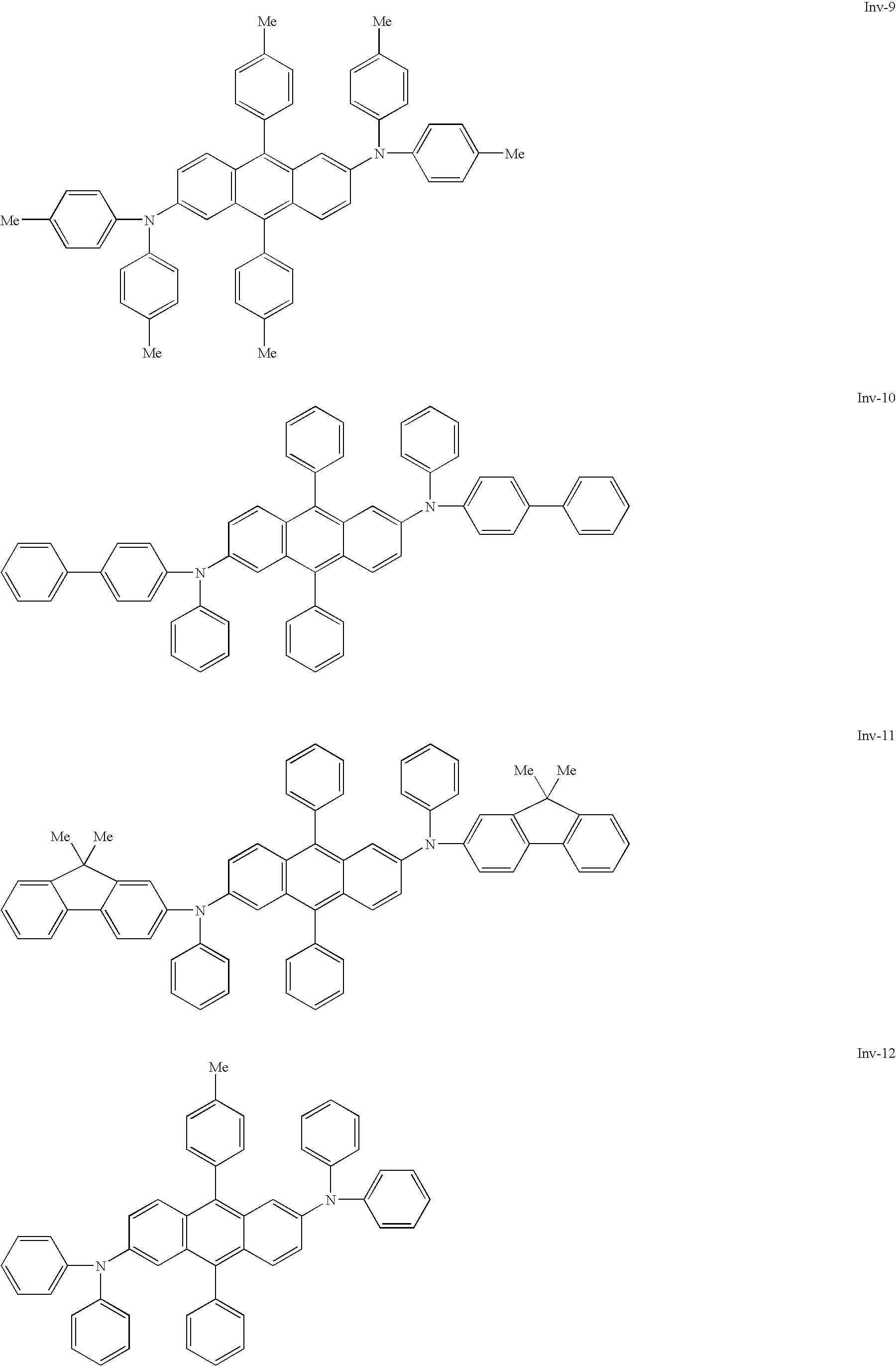

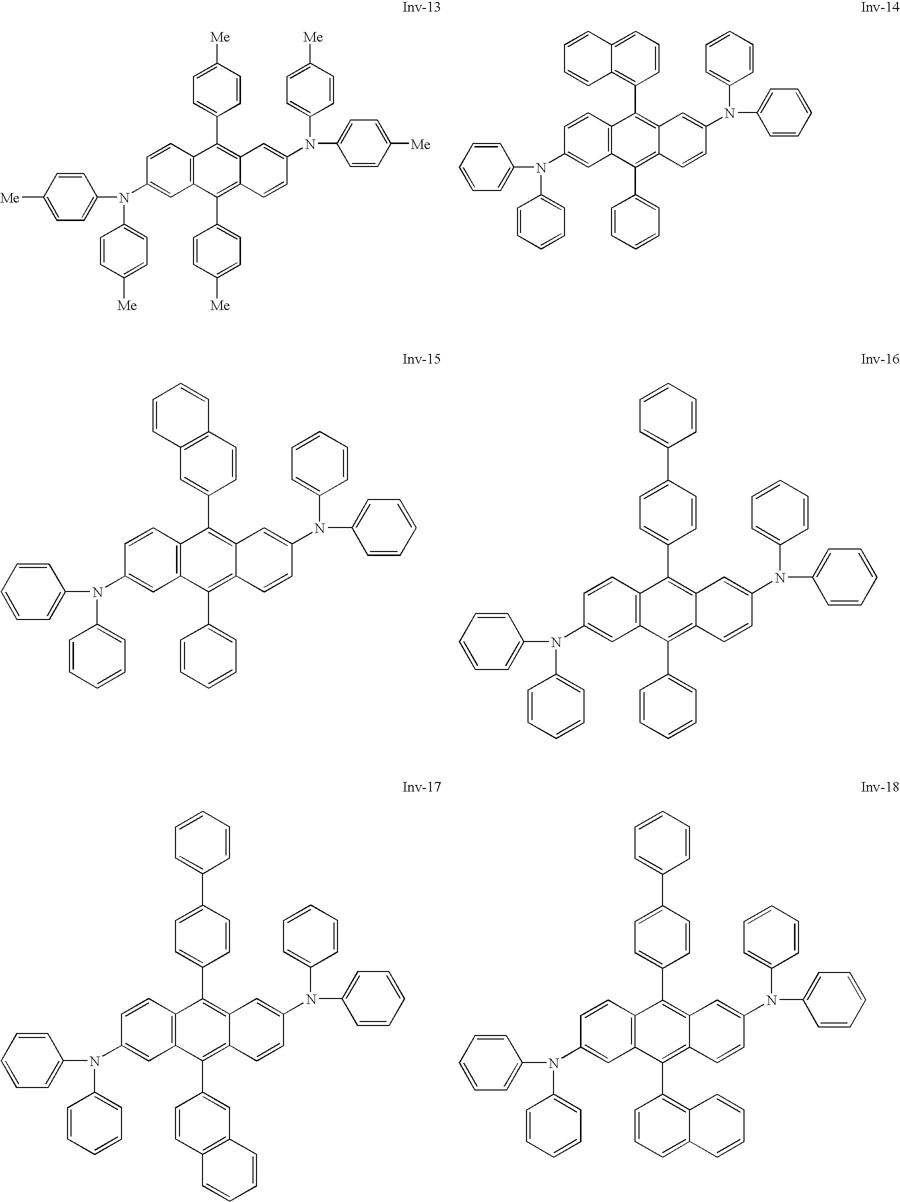

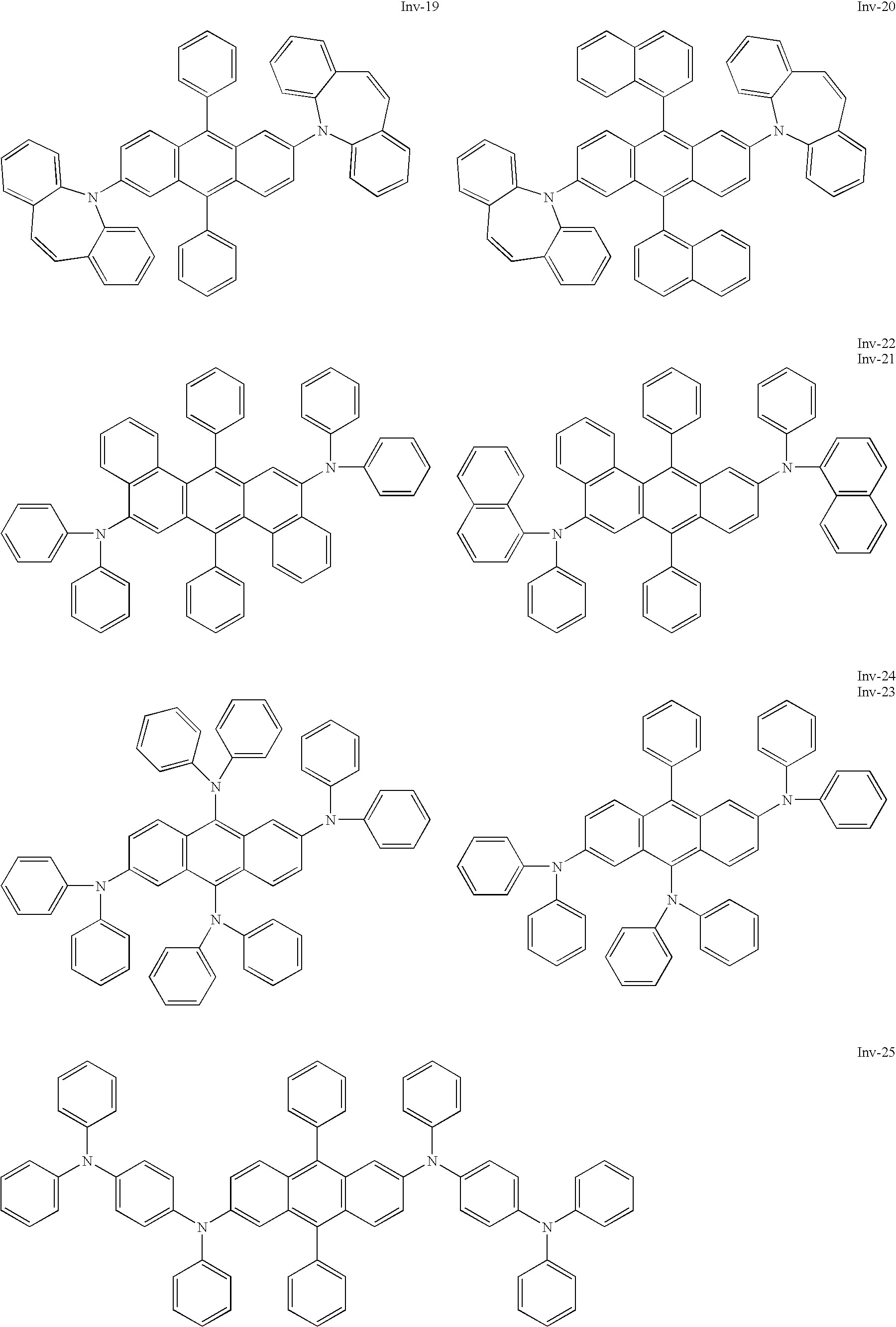

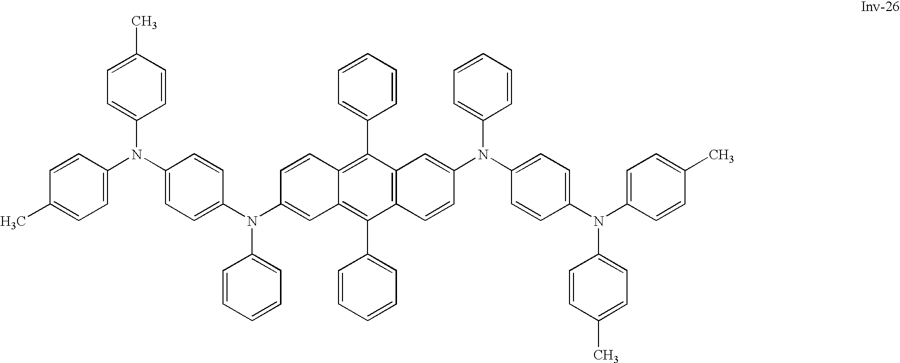

Other aromatic amines can also be useful as the second material in HIL 120. For example, the second material in HIL 120 can be a chemical compound of Formula V

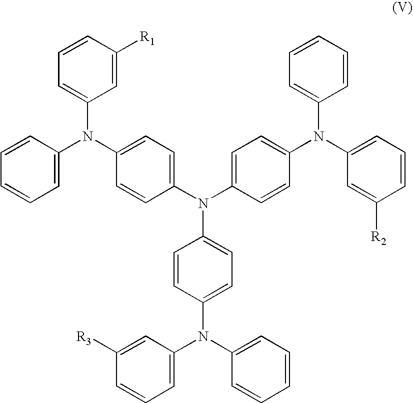

wherein R₁-R₃ represent hydrogen on an independently selected substituent, such as a methyl group or a phenyl group.

Specifically, the organic material for use as a second material in the HIL 120 can be a chemical compound of Formula Va (4,4′,4″-tris[(3-methylphenyl)phenylamino]triphenylamine (m-TDATA).

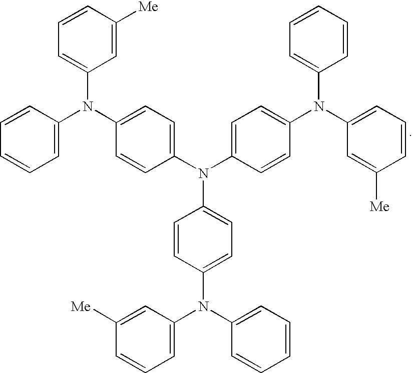

Dihydrophenazine derivatives can also be useful as the second material in HIL 120. For example, the second material in HIL 120 can be a dihydrophenazine of Formula VI

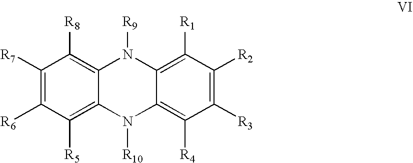

wherein:

R₁ represent hydrogen on an independently selected substituent, such as a methyl group or a phenyl group, or connected to R₂ to form 5 or 6 member ring systems;

R₄ represent hydrogen on an independently selected substituent, such as a methyl group or a phenyl group, or connected to R₃ to form 5 or 6 member ring systems;

R₅ represent hydrogen on an independently selected substituent, such as a methyl group or a phenyl group, or connected to R₆ to form 5 or 6 member ring systems;

R₈ represent hydrogen on an independently selected substituent, such as a methyl group or a phenyl group, or connected to R₇ to form 5 or 6 member ring systems;

R₂ and R₃ individually represent hydrogen on an independently selected substituent, such as a methyl group or a phenyl group, or are connected to form 5 or 6 member ring systems;

R₆ and R₇ individually represent hydrogen on an independently selected substituent, such as a methyl group or a phenyl group, or are connected to form 5 or 6 member ring systems; and

R₉ and R₁₀ represent hydrogen on an independently selected substituent, such as a methyl group or a phenyl group.

Illustrative examples of compounds of Formula VI useful in the present invention are listed below.

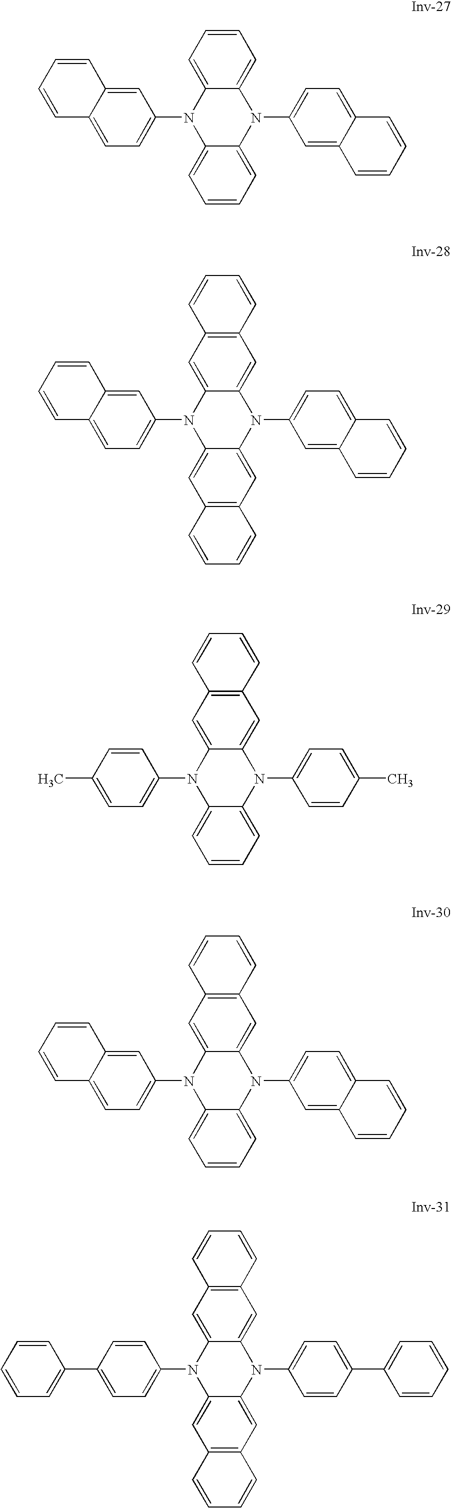

It should be noted that in addition to the aforementioned types of materials, other materials useful as the second materials in the HIL 120 can be selected from any materials, having an oxidation potential less than 0.8 V. vs. SCE except metal complexes. Metal complexes were not used as the second materials, such as copper phthalocyanine, because the metal complexes can cause severe optical absorption resulting in reduced light output.

The oxidation potentials of some second materials are listed in Table 2:

TABLE 2
Oxidation Potentials

| | Oxidation Potential |
|---|---|
| Compound | (vs. SCE, V) |
| m-TDATA | 0.46 |
| Inv-1 | 0.68 |
| Inv-3 | 0.60 |
| Inv-23 | 0.67 |
| Inv-27 | 0.354 |
| Inv-28 | 0.369 |
| Inv-29 | 0.477 |
| Inv-30 | 0.518 |
| Inv-31 | 0.672 |

The organic materials used to form the HIL 120 are suitably deposited through a vapor-phase method such as thermal evaporation, but can be deposited from a fluid, for example, from a solvent with an optional binder to improve film formation. If the material is a polymer, solvent deposition is useful but other methods can be used, such as sputtering or thermal transfer from a donor sheet. Preferably, the organic materials used to form the HIL 120 are deposited by thermal evaporation under reduced pressure.

The HIL 120 contains, by volume, more than 50% of the first material and less than 50% of the second material. Suitably, it contains, by mole ratio, more than 60% of the first material and less than 40% of the second material. Preferably, the HIL 120 contains, by volume, more than 70% of the first material and less than 30% of the second material. The volume described above should include the sum total of any compounds present that meets the redox criteria of either the first or second compound. In other words, there can be more than one first or more than one second compound and the volume refers to the total amount of the compounds that fit either type. The determination of the volume between the first and second materials in the HIL should not include any additional materials that can be present in the HIL that do not meet the redox requirements of either the first or second materials.

The thickness of the HIL 120 is in the range of from 0.1 nm to 150 nm, preferably, in the range of from 1.0 nm to 50 nm.

### Hole-Transporting Layer (HTL) 130

The HTL 130 contains at least one hole-transporting material such as an aromatic tertiary amine, where the latter is understood to be a compound containing at least one trivalent nitrogen atom that is bonded only to carbon atoms, at least one of which is a member of an aromatic ring. In one form the aromatic tertiary amine is an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals or at least one active hydrogen-containing group are disclosed by Brantley, et al. in U.S. Pat. No. 3,567,450 and U.S. Pat. No. 3,658,520.

A more preferred class of aromatic tertiary amines are those which include at least two aromatic tertiary amine moieties as described in U.S. Pat. No. 4,720,432 and U.S. Pat. No. 5,061,569. Such compounds include those represented by structural Formula (A)

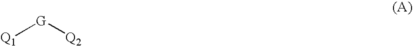

wherein:

Q₁ and Q₂ are independently selected aromatic tertiary amine moieties; and

G is a linking group such as an arylene, cycloalkylene, or alkylene group of a carbon to carbon bond.

In one embodiment, at least one of Q₁ or Q₂ contains a polycyclic fused ring structure, e.g., a naphthalene. When G is an aryl group, it is conveniently a phenylene, biphenylene, or naphthalene moiety.

A useful class of triarylamines satisfying structural Formula A and containing two triarylamine moieties is represented by structural Formula (B)

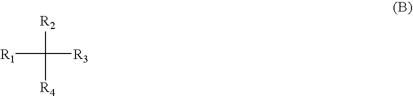

wherein:

R₁ and R₂ each independently represents a hydrogen atom, an aryl group, or an alkyl group or R₁ and R₂ together represent the atoms completing a cycloalkyl group; and

R₃ and R₄ each independently represents an aryl group, which is in turn substituted with a diaryl substituted amino group, as indicated by structural Formula (C)

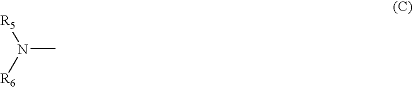

wherein R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by Formula (C), linked through an arylene group. Useful tetraaryldiamines include those represented by Formula (D)

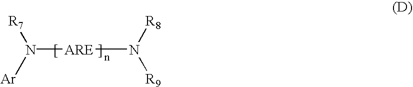

wherein:

each ARE is an independently selected arylene group, such as a phenylene or anthracene moiety;

n is an integer of from 1 to 4; and

Ar, R₇, R₈, and R₉ are independently selected aryl groups. In a typical embodiment, at least one of Ar, R₇, R₈, and R₉ is a polycyclic fused ring structure, e.g., a naphthalene.

Another class of the hole-transporting material includes a material of formula (E):

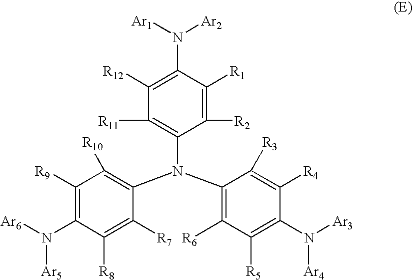

In formula (E), Ar₁-Ar₆ independently represent aromatic groups, for example, phenyl groups or tolyl groups;

R₁-R₁₂ independently represent hydrogen or independently selected substituent, for example an alkyl group containing from 1 to 4 carbon atoms, an aryl group, a substituted aryl group.

The various alkyl, alkylene, aryl, and arylene moieties of the foregoing structural Formulae (A), (B), (C), (D), and (E) can each in turn be substituted. Typical substituents include alkyl groups, alkoxy groups, aryl groups, aryloxy groups, and halogen such as fluoride, chloride, and bromide. The various alkyl and alkylene moieties typically contain from about 1 to 6 carbon atoms. The cycloalkyl moieties can contain from 3 to about 10 carbon atoms, but typically contain five, six, or seven ring carbon atoms, e.g. cyclopentyl, cyclohexyl, and cycloheptyl ring structures. The aryl and arylene moieties are typically phenyl and phenylene moieties.

The HTL is formed of a single or a mixture of aromatic tertiary amine compounds. Specifically, one can employ a triarylamine, such as a triarylamine satisfying the Formula (B), in combination with a tetraaryldiamine, such as indicated by Formula (D). When a triarylamine is employed in combination with a tetraaryldiamine, the latter is positioned as a layer interposed between the triarylamine and the electron injecting and transporting layer. Aromatic tertiary amines are useful as hole-injecting materials also. Illustrative of useful aromatic tertiary amines are the following:

1,1-bis(4-di-p-tolylaminophenyl)cyclohexane;

1,1-bis(4-di-p-tolylaminophenyl)-4-phenylcyclohexane;

1,5-bis[N-(1-naphthyl)-N-phenylamino]naphthalene;

2,6-bis(di-p-tolylamino)naphthalene;

2,6-bis[di-(1-naphthyl)amino]naphthalene;

2,6-bis[N-(1-naphthyl)-N-(2-naphthyl)amino]naphthalene;

2,6-bis[N,N-di(2-naphthyl)amine]fluorene;

4-(di-p-tolylamino)-4′-[4(di-p-tolylamino)-styryl]stilbene;

4,4′-bis(diphenylamino)quadriphenyl;

4,4″-bis[N-(1-anthryl)-N-phenylamino]-p-terphenyl;

4,4′-bis[N-(1-coronenyl)-N-phenylamino]biphenyl;

4,4′-bis[N-(1-naphthyl)-N-phenylamino]biphenyl (NPB);

4,4′-bis[N-(1-naphthyl)-N-(2-naphthyl)amino]biphenyl (TNB);

4,4″-bis[N-(1-naphthyl)-N-phenylamino]p-terphenyl;

4,4′-bis[N-(2-naphthacenyl)-N-phenylamino]biphenyl;

4,4′-bis[N-(2-naphthyl)-N-phenylamino]biphenyl;

4,4′-bis[N-(2-perylenyl)-N-phenylamino]biphenyl;

4,4′-bis[N-(2-phenanthryl)-N-phenylamino]biphenyl;

4,4′-bis[N-(2-pyrenyl)-N-phenylamino]biphenyl;

4,4′-bis[N-(3-acenaphthenyl)-N-phenylamino]biphenyl;

4,4′-bis[N-(3-methylphenyl)-N-phenylamino]biphenyl (TPD);

4,4′-bis[N-(8-fluoranthenyl)-N-phenylamino]biphenyl;

4,4′-bis[N-(9-anthryl)-N-phenylamino]biphenyl;

4,4′-bis{N-phenyl-N-[4-(1-naphthyl)-phenyl]amino}biphenyl;

4,4′-bis[N-phenyl-N-(2-pyrenyl)amino]biphenyl;

4,4′,4″-tris[(3-methylphenyl)phenylamino]triphenylamine (m-TDATA);

Bis(4-dimethylamino-2-methylphenyl)-phenylmethane;

N-phenylcarbazole;

N,N′-bis[4-([1,1′-biphenyl]-4-ylphenylamino)phenyl]-N,N′-di-1-naphthalenyl-[1,1′-biphenyl]-4,4′-diamine;

N,N′-bis[4-(di-1-naphthalenylamino)phenyl]-N,N′-di-1-naphthalenyl-[1,1′-biphenyl]-4,4′-diamine;

N,N′-bis[4-[(3-methylphenyl)phenylamino]phenyl]-N,N′-diphenyl-[1,1′-biphenyl]-4,4′-diamine;

N,N-bis[4-(diphenylamino)phenyl]-N′,N′-diphenyl-[1,1′-biphenyl]-4,4′-diamine;

N,N′-di-1-naphthalenyl-N,N′-bis[4-(1-naphthalenylphenylamino)phenyl]-[1,1′-biphenyl]-4,4′-diamine;

N,N′-di-1-naphthalenyl-N,N′-bis[4-(2-naphthalenylphenylamino)phenyl]-[1,1′-biphenyl]-4,4′-diamine;

N,N,N-tri(p-tolyl)amine;

N,N,N′,N′-tetra-p-tolyl-4-4′-diaminobiphenyl;

N,N,N′,N′-tetraphenyl-4,4′-diaminobiphenyl;

N,N,N′,N′-tetra-1-naphthyl-4,4′-diaminobiphenyl;

N,N,N′,N′-tetra-2-naphthyl-4,4′-diaminobiphenyl; and

N,N,N′,N′-tetra(2-naphthyl)-4,4″-diamino-p-terphenyl.

Another class of useful hole-transporting materials includes polycyclic aromatic compounds as described in EP 1 009 041. Tertiary aromatic amines with more than two amine groups can be used including oligomeric materials. In addition, polymeric hole-transporting materials are used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

The thickness of the HTL 130 is in the range of from 5 nm to 200 nm, preferably, in the range of from 10 nm to 150 nm.

### Light-Emitting Layer (LEL) 150

The LEL 150 in the devices as shown in FIGS. 1 and 2 include a luminescent fluorescent or phosphorescent material where electroluminescence is produced as a result of electron-hole pair recombination in this region. The light-emitting layer can be comprised of a single material, but more commonly contains at least one host material doped with at least one guest emitting material or materials where light emission comes primarily from the emitting materials and can be of any color. This guest emitting material is often referred to as a light-emitting dopant material. The host materials in the light-emitting layer can be an electron-transporting material, as defined below, a hole-transporting material, as defined above, or another material or combination of materials that support hole-electron recombination. The dopant material in the light-emitting layer is typically chosen from highly fluorescent dyes and phosphorescent compounds, e.g., transition metal complexes as described in WO 98/55561, WO 00/18851, WO 00/57676, and WO 00/70655. Emitting materials are typically incorporated at 0.01 to 20% by volume of the host material.

The host and dopant materials in the light-emitting layer can be small nonpolymeric molecules or polymeric materials including polyfluorenes and polyvinylarylenes, e.g., poly(p-phenylenevinylene), PPV. In the case of polymers, small molecule emitting materials can be molecularly dispersed into a polymeric host, or the emitting materials can be added by copolymerizing a minor constituent into a host polymer.

An important relationship for choosing a dopant material is a comparison of the electron energy bandgap, which is defined as the energy difference between the highest occupied molecular orbital and the lowest unoccupied molecular orbital of the molecule. For efficient energy transfer from the host material to the dopant material, a necessary condition is that the bandgap of the dopant material is smaller than that of the host material. For phosphorescent emitters (including materials that emit from a triplet excited state, i.e., so-called “triplet emitters”) it is also important that the triplet energy level of the host be high enough to enable energy transfer from host to emitting dopant material.

Host and dopant materials in the light-emitting layer known to be of use include, but are not limited to, those disclosed in U.S. Pat. No. 4,768,292, U.S. Pat. No. 5,141,671, U.S. Pat. No. 5,150,006, U.S. Pat. No. 5,151,629, U.S. Pat. No. 5,405,709, U.S. Pat. No. 5,484,922, U.S. Pat. No. 5,593,788, U.S. Pat. No. 5,645,948, U.S. Pat. No. 5,683,823, U.S. Pat. No. 5,755,999, U.S. Pat. No. 5,928,802, U.S. Pat. No. 5,935,720, U.S. Pat. No. 5,935,721, U.S. Pat. No. 6,020,078, U.S. Pat. No. 6,475,648, U.S. Pat. No. 6,534,199, U.S. Pat. No. 6,661,023, US 2002/0127427 A1, US 2003/0198829 A1, US 2003/0203234 A1, US 2003/0224202 A1, and US 2004/0001969 A1.

Metal complexes of 8-hydroxyquinoline (oxine) and similar derivatives constitute one class of useful host compounds capable of supporting electroluminescence. Illustrative of useful chelated oxinoid compounds are the following:

CO-1: Aluminum trisoxine [alias, tris(8-quinolinolato)aluminum(III)];

CO-2: Magnesium bisoxine [alias, bis(8-quinolinolato)magnesium(II)];

CO-3: Bis[benzo {f}-8-quinolinolato]zinc (II);

CO-4: Bis(2-methyl-8-quinolinolato)aluminum(III)-μ-oxo-bis(2-methyl-8-quinolinolato) aluminum(III);

CO-5: Indium trisoxine [alias, tris(8-quinolinolato)indium];

CO-6: Aluminum tris(5-methyloxine) [alias, tris(5-methyl-8-quinolinolato) aluminum(III)];

CO-7: Lithium oxine [alias, (8-quinolinolato)lithium(I)];

CO-8: Gallium oxine [alias, tris(8-quinolinolato)gallium(III)]; and

CO-9: Zirconium oxine [alias, tetra(8-quinolinolato)zirconium(IV)].

Another class of useful host materials includes derivatives of anthracene, such as those described in U.S. Pat. No. 5,935,721, U.S. Pat. No. 5,972,247, U.S. Pat. No. 6,465,115, U.S. Pat. No. 6,534,199, U.S. Pat. No. 6,713,192, US 2002/0048687 A1, US 2003/0072966 A1, and WO 2004/018587. Some examples include derivatives of 9,10-dinaphthylanthracene derivatives and 9-naphthyl-10-phenylanthracene. Other useful classes of host materials include distyrylarylene derivatives as described in U.S. Pat. No. 5,121,029, and benzazole derivatives, for example, 2,2′,2″-(1,3,5-phenylene)tris[1-phenyl-1H-benzimidazole].

Desirable host materials are capable of forming a continuous film. The light-emitting layer can contain more than one host material in order to improve the device's film morphology, electrical properties, light emission efficiency, and lifetime. Mixtures of electron-transporting and hole-transporting materials are known as useful hosts. In addition, mixtures of the above listed host materials with hole-transporting or electron-transporting materials can make suitable hosts.

Useful fluorescent dopant materials include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrylium and thiapyrylium compounds, fluorene derivatives, periflanthene derivatives, indenoperylene derivatives, bis(azinyl)amine boron compounds, bis(azinyl)methane boron compounds, derivatives of distryrylbenzene and distyrylbiphenyl, and carbostyryl compounds. Among derivatives of distyrylbenzene, particularly useful are those substituted with diarylamino groups, informally known as distyrylamines. Illustrative examples of useful materials include, but are not limited to, the following:

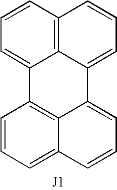

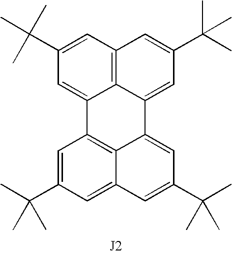

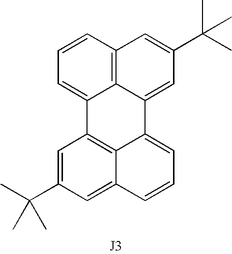

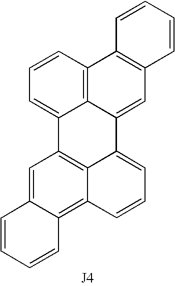

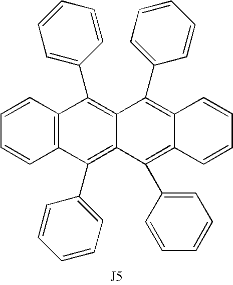

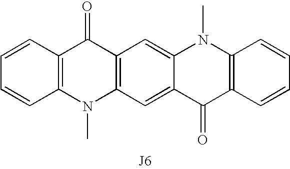

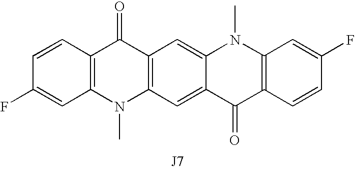

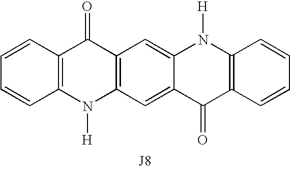

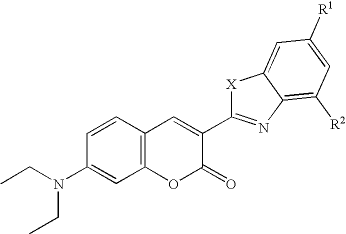

| | X | R1 | R2 |
|---|---|---|---|
| J9 | O | H | H |
| J10 | O | H | Methyl |
| J11 | O | Methyl | H |
| J12 | O | Methyl | Methyl |
| J13 | O | H | t-butyl |
| J14 | O | t-butyl | H |
| J15 | O | t-butyl | t-butyl |
| J16 | S | H | H |
| J17 | S | H | Methyl |
| J18 | S | Methyl | H |
| J19 | S | Methyl | Methyl |
| J20 | S | H | t-butyl |
| J21 | S | t-butyl | H |
| J22 | S | t-butyl | t-butyl |

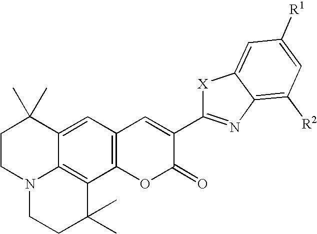

| | X | R1 | R2 |
|---|---|---|---|
| J23 | O | H | H |
| J24 | O | H | Methyl |
| J25 | O | Methyl | H |
| J26 | O | Methyl | Methyl |
| J27 | O | H | t-butyl |
| J28 | O | t-butyl | H |
| J29 | O | t-butyl | t-butyl |
| J30 | S | H | H |
| J31 | S | H | Methyl |
| J32 | S | Methyl | H |
| J33 | S | Methyl | Methyl |
| J34 | S | H | t-butyl |
| J35 | S | t-butyl | H |
| J36 | S | t-butyl | t-butyl |

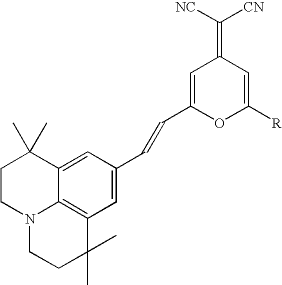

| | R |
|---|---|
| J37 | Phenyl |
| J38 | Methyl |
| J39 | t-butyl |
| J40 | Mesityl |

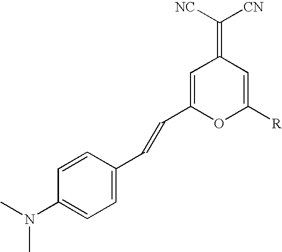

| | R |
|---|---|
| J41 | phenyl |
| J42 | methyl |
| J43 | t-butyl |
| J44 | mesityl |

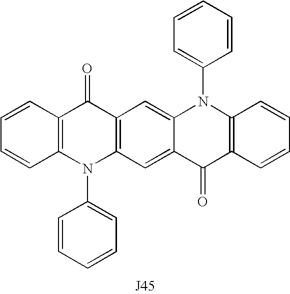

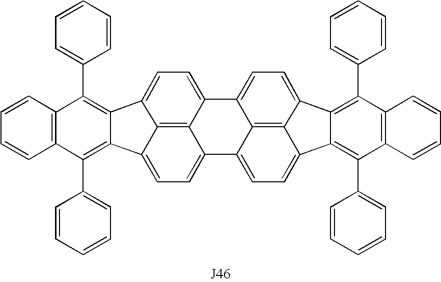

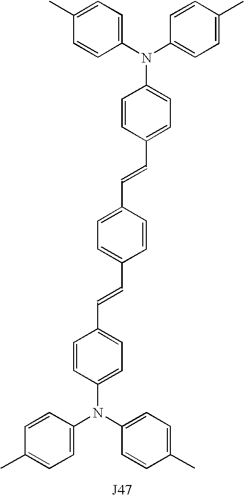

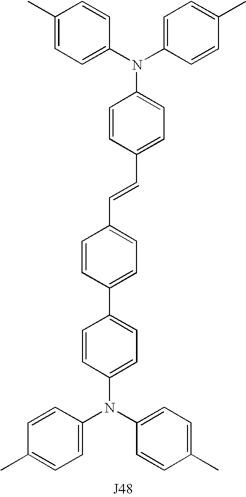

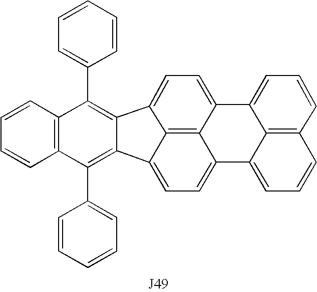

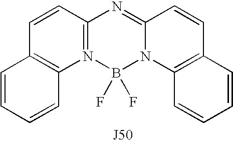

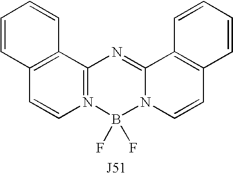

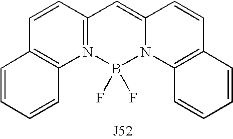

Suitable host materials for phosphorescent emitters should be selected so that the triplet exciton can be transferred efficiently from the host material to the phosphorescent dopant material. For this transfer to occur, it is a highly desirable condition that the excited state energy of the phosphorescent dopant material be lower than the difference in energy between the lowest triplet state and the ground state of the host material. However, the band gap of the host material should not be chosen so large as to cause an unacceptable increase in the drive voltage of the OLED. Suitable host materials are described in WO 00/70655 A2, WO 01/39234 A2, WO 01/93642 A1, WO 02/074015 A2, WO 02/15645 A1, and US 2002/0117662 A1. Suitable host materials include certain aryl amines, triazoles, indoles and carbazole compounds. Examples of desirable host materials are 4,4′-N,N′-dicarbazole-biphenyl (CBP), 2,2′-dimethyl-4,4′-N,N′-dicarbazole-biphenyl, m-(N,N′-dicarbazole)benzene, and poly(N-vinylcarbazole), including their derivatives.

Examples of useful phosphorescent dopant materials that can be used in light-emitting layers of this invention include, but are not limited to, those described in WO 00/57676, WO 00/70655, WO 01/41512 A1, WO 02/15645 A1, WO 01/93642 A1, WO 01/39234 A2, WO 02/074015 A2, WO 02/071813 A1, U.S. Pat. No. 6,458,475, U.S. Pat. No. 6,573,651, U.S. Pat. No. 6,413,656, U.S. Pat. No. 6,515,298, U.S. Pat. No. 6,451,415, U.S. Pat. No. 6,097,147, U.S. Pat. No. 6,451,455, US 2003/0017361 A1, US 2002/0197511 A1, US 2003/0072964 A1, US 2003/0068528 A1, US 2003/0124381 A1, US 2003/0059646 A1, US 2003/0054198 A1, US 2002/0100906 A1, US 2003/0068526 A1, US 2003/0068535 A1, US 2003/0141809 A1, US 2003/0040627 A1, US 2002/0121638 A1, EP 1 239 526 A2, EP 1 238 981 A2, EP 1 244 155 A2, JP 2003-073387, JP 2003-073388, JP 2003-059667, and JP 2003-073665. Preferably, useful phosphorescent dopant materials include transition metal complexes, such as iridium and platinum complexes.

In some cases it is useful for the LEL in the devices to emit broadband light, for example white light. Multiple dopant materials can be added to one or more layers in order to produce a white-emitting OLED, for example, by combining blue- and yellow-emitting materials, cyan- and red-emitting materials, or red-, green-, and blue-emitting materials. White-emitting devices are described, for example, in EP 1 187 235, EP 1 182 244, U.S. Pat. No. 5,683,823, U.S. Pat. No. 5,503,910, U.S. Pat. No. 5,405,709, U.S. Pat. No. 5,283,182, U.S. Pat. No. 6,627,333, U.S. Pat. No. 6,696,177, U.S. Pat. No. 6,720,092, and US 2002/0186214 A1, US 2002/0025419 A1, and US 2004/0009367 A1. In some of these systems, the host material for one light-emitting layer is a hole-transporting material.

The thickness of LEL 150 is in the range of from 1 nm to 200 nm, preferably, in the range of from 5 nm to 100 nm.

### Electron-Transporting Layer (ETL) 170

The ETL 170 contains at least one electron-transporting material such as benzazole, phenanthroline, 1,3,4-oxadiazole, triazole, triazine, or triarylborane.

A preferred class of benzazoles is described by Shi et al. in U.S. Pat. No. 5,645,948 and U.S. Pat. No. 5,766,779. Such compounds are represented by structural formula (K):

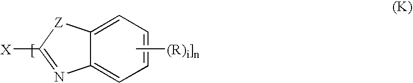

In formula (K), n is selected from 2 to 8;

Z is independently O, NR or S;

R and R′ are individually hydrogen; alkyl of from 1 to 24 carbon atoms, for example, propyl, t-butyl, heptyl, and the like; aryl or hetero-atom substituted aryl of from 5 to 20 carbon atoms, for example, phenyl and naphthyl, furyl, thienyl, pyridyl, quinolinyl and other heterocyclic systems; or halo such as chloro, fluoro; or atoms necessary to complete a fused aromatic ring; and

X is a linkage unit containing carbon, alkyl, aryl, substituted alkyl, or substituted aryl, which conjugately or unconjugately connects the multiple benzazoles together.

An example of a useful benzazole is 2,2′,2″-(1,3,5-phenylene)tris[1-phenyl-1H-benzimidazole] (TPBI) (see Formula K-1) represented as shown below:

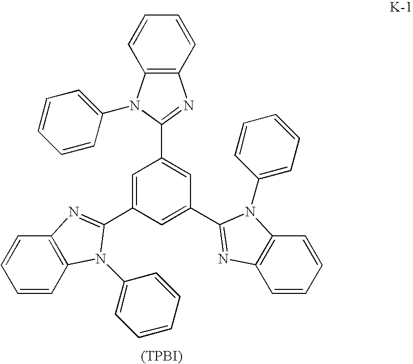

Another class of the electron-transporting materials includes various substituted phenanthrolines as represented by formula (L):

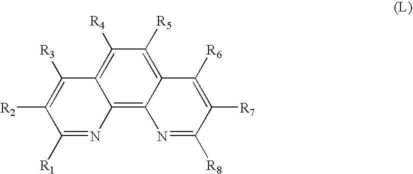

In formula (L), R₁-R₈ are independently hydrogen, alkyl group, aryl or substituted aryl group, and at least one of R₁-R₈ is aryl group or substituted aryl group.

Examples of particularly suitable materials of this class are 2,9-dimethyl-4,7-diphenyl-1,10-phenanthroline (BCP) (see Formula L-1) and 4,7-diphenyl-1,10-phenanthroline (Bphen) (see Formula L-2).

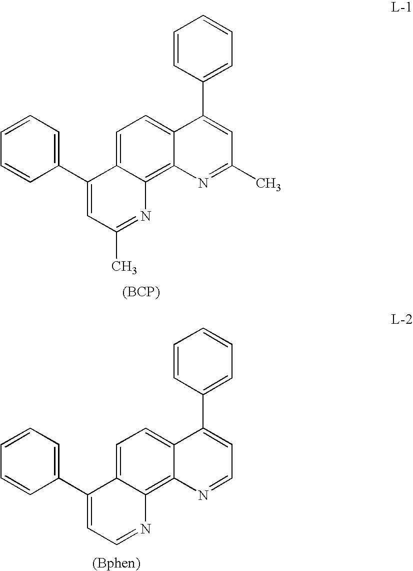

The triarylboranes that function as the electron-transporting materials in the present invention can be selected from compounds having the chemical formula (M):

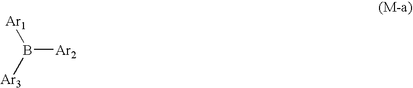

wherein

Ar₁ to Ar₃ are independently an aromatic hydrocarbocyclic group or an aromatic heterocyclic group which can have a substituent. It is preferable that compounds having the above structure are selected from formula (M-b):

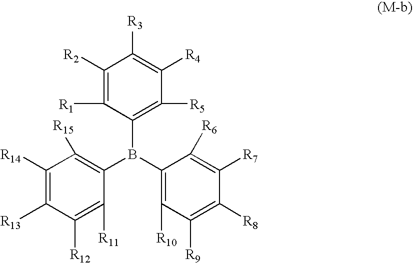

wherein R₁-R₁₅ are independently hydrogen, fluoro, cyano, trifluoromethyl, sulfonyl, alkyl, aryl or substituted aryl group.

Specific representative embodiments of the triarylboranes include:

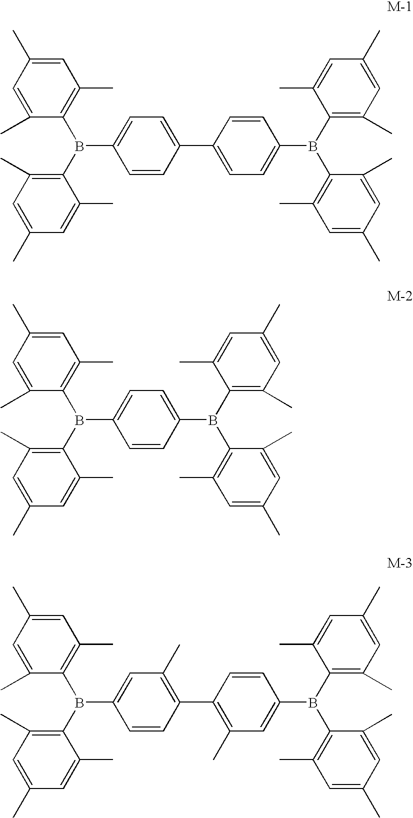

The electron-transporting materials in the present invention can be selected from substituted 1,3,4-oxadiazoles. Illustrative of the useful substituted oxadiazoles are the following:

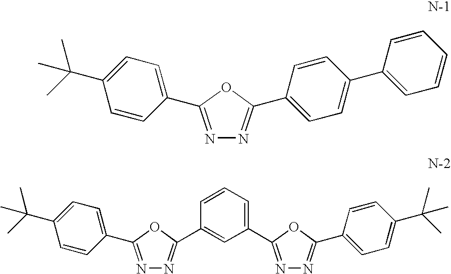

The electron-transporting materials in the present invention also can be selected from substituted 1,2,4-triazoles. An example of a useful triazole is 3-phenyl-4-(1-naphtyl)-5-phenyl-1,2,4-triazole:

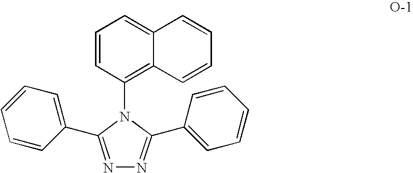

The electron-transporting materials in the present invention also can be selected from substituted 1,3,5-triazines. Examples of suitable materials are:

2,4,6-tris(diphenylamino)-1,3,5-triazine;

2,4,6-tricarbazolo-1,3,5-triazine;

2,4,6-tris(N-phenyl-2-naphthylamino)-1,3,5-triazine;

2,4,6-tris(N-phenyl-1-naphthylamino)-1,3,5-triazine;

4,4′,6,6′-tetraphenyl-2,2′-bi-1,3,5-triazine;

2,4,6-tris([1,1′:3′,1″-terphenyl]-5′-yl)-1,3,5-triazine.

In addition to the aforementioned electron-transporting materials, the electron-transporting materials for use in the ETL 170 can also be selected from, but are not limited to, chelated oxinoid compounds, anthracene derivatives, pyridine-based materials, imidazoles, oxazoles, thiazoles and their derivatives, polybenzobisazoles, cyano-containing polymers and perfluorinated materials.

For example, the electron-transporting materials for use in the ETL 170 can be a metal chelated oxinoid compound including chelates of oxine itself (also commonly referred to as 8-quinolinol or 8-hydroxyquinoline). Exemplary of contemplated oxinoid compounds are those satisfying structural Formula (R)

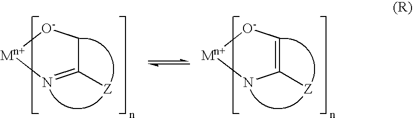

wherein:

M represents a metal;

n is an integer of from 1 to 4; and

Z independently in each occurrence represents the atoms completing a nucleus having at least two fused aromatic rings.

Particularly useful electron-transporting aluminum or gallium complex host materials are represented by Formula (R-a).

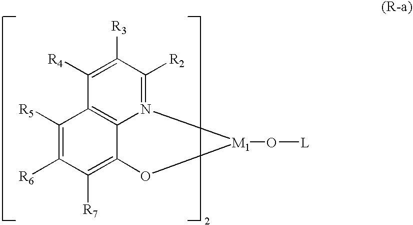

In Formula (R-a), M₁ represents Al or Ga. R₂-R₇ represent hydrogen or an independently selected substituent. Desirably, R₂ represents an electron-donating group. Suitably, R₃ and R₄ each independently represent hydrogen or an electron donating substituent. A preferred electron-donating group is alkyl such as methyl. Preferably, R₅, R₆, and R₇ each independently represent hydrogen or an electron-accepting group. Adjacent substituents, R₂-R₇, can combine to form a ring group. L is an aromatic moiety linked to the aluminum by oxygen, which can be substituted with substituent groups such that L has from 6 to 30 carbon atoms.

Illustrative of useful chelated oxinoid compounds for use in the ETL 170 are the following:

R-1: Aluminum trisoxine [alias, tris(8-quinolinolato)aluminum(III) or Alq or Alq3];

R-2: Magnesium bisoxine [alias, bis(8-quinolinolato)magnesium(II)];

R-3: Bis[benzo {f}-8-quinolinolato]zinc (II);

R-4: Bis(2-methyl-8-quinolinolato)aluminum(Ill)-μ-oxo-bis(2-methyl-8-quinolinolato) aluminum(III);

R-5: Indium trisoxine [alias, tris(8-quinolinolato)indium];

R-6: Aluminum tris(5-methyloxine) [alias, tris(5-methyl-8-quinolinolato) aluminum(III)];

R-7: Lithium oxine [alias, (8-quinolinolato)lithium(I)];

R-8: Gallium oxine [alias, tris(8-quinolinolato)gallium(III)]; and

R-9: Zirconium oxine [alias, tetra(8-quinolinolato)zirconium(IV)]

R-a-1: Aluminum(III) bis(2-methyl-8-hydroxyquinoline)-4-phenylphenolate [alias, Balq].

As another example, anthracene derivatives according to Formula (S) as useful in the ETL 170:

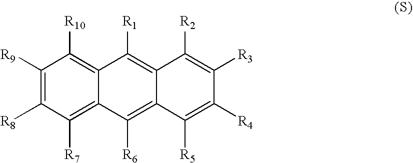

wherein R₁-R₁₀ are independently chosen from hydrogen, alkyl groups for 1-24 carbon atoms or aromatic groups from 1-24 carbon atoms. Particularly preferred are compounds where R₁ and R₆ are phenyl, biphenyl or napthyl, R₃ is phenyl, substituted phenyl or napthyl and R₂, R₄, R₅, R₇-R₁₀ are all hydrogen. Some illustrative examples of suitable anthracenes are:

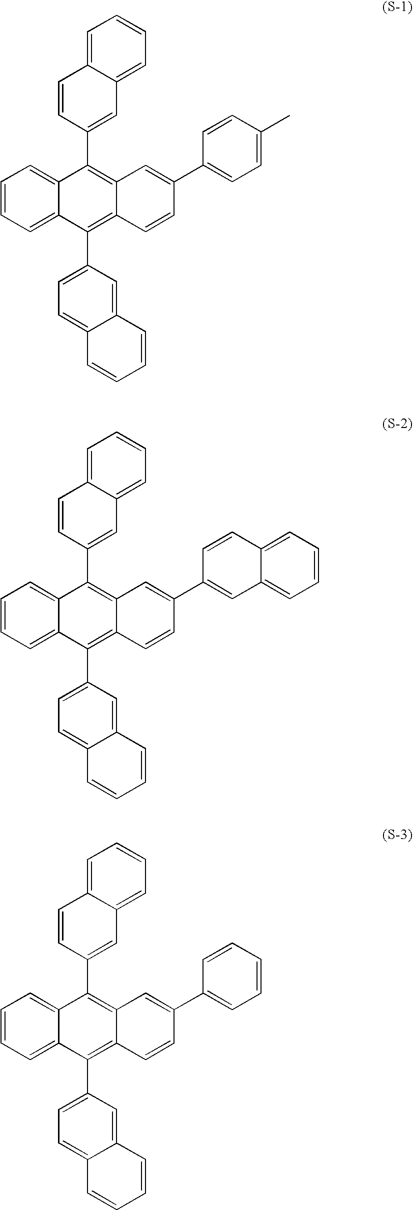

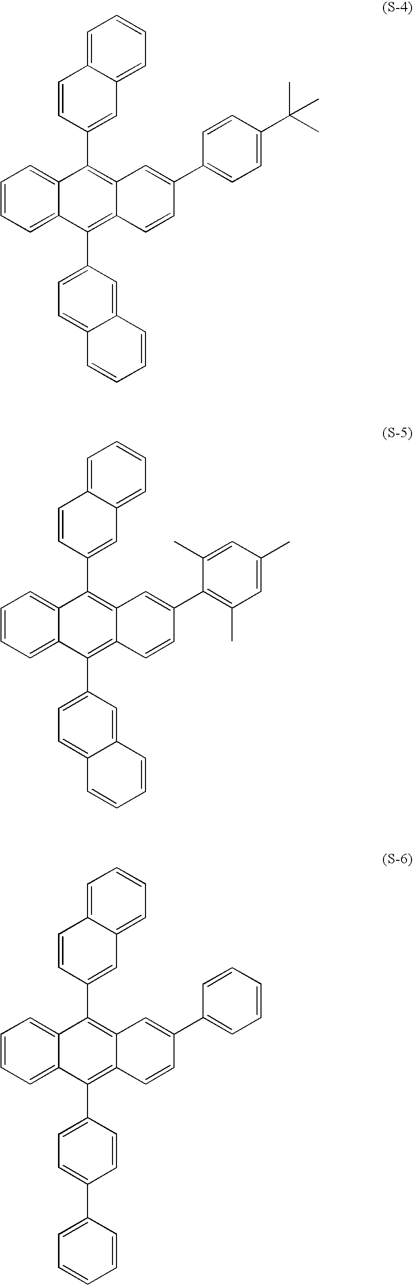

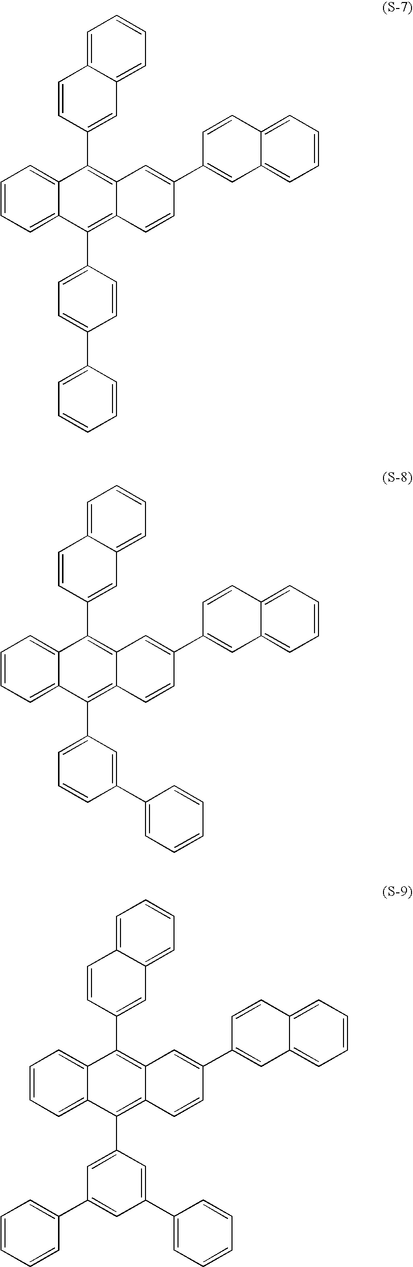

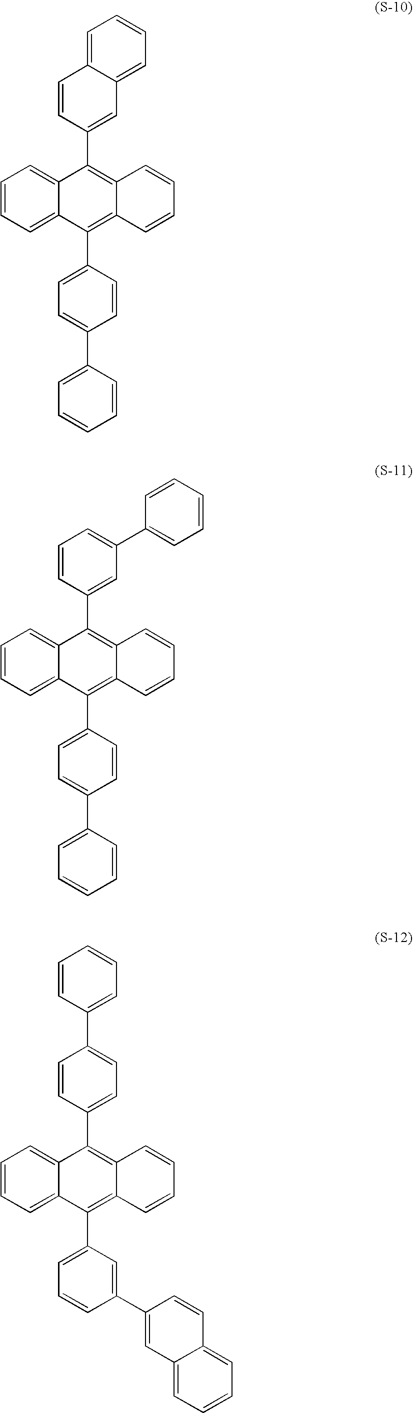

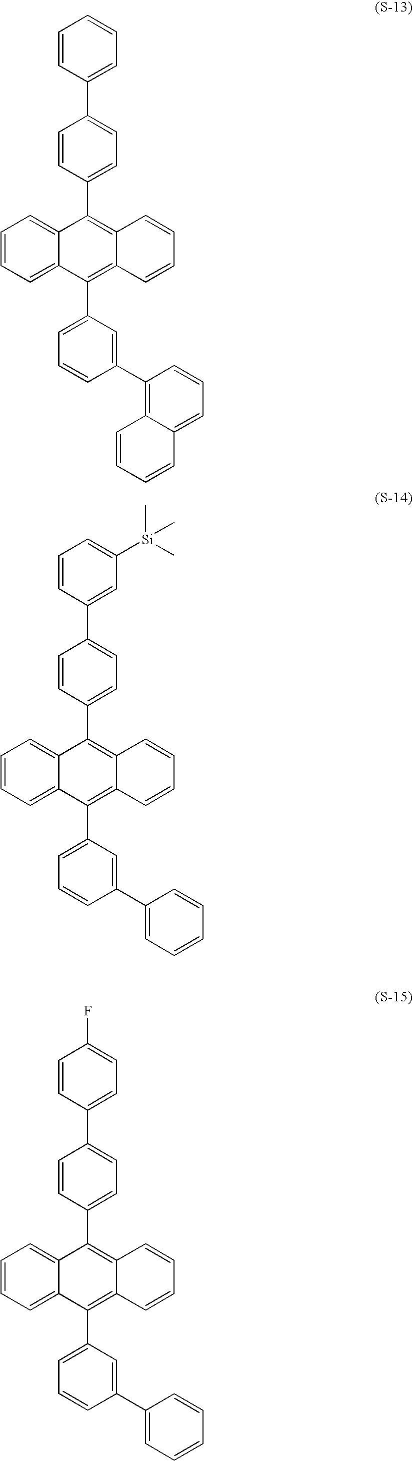

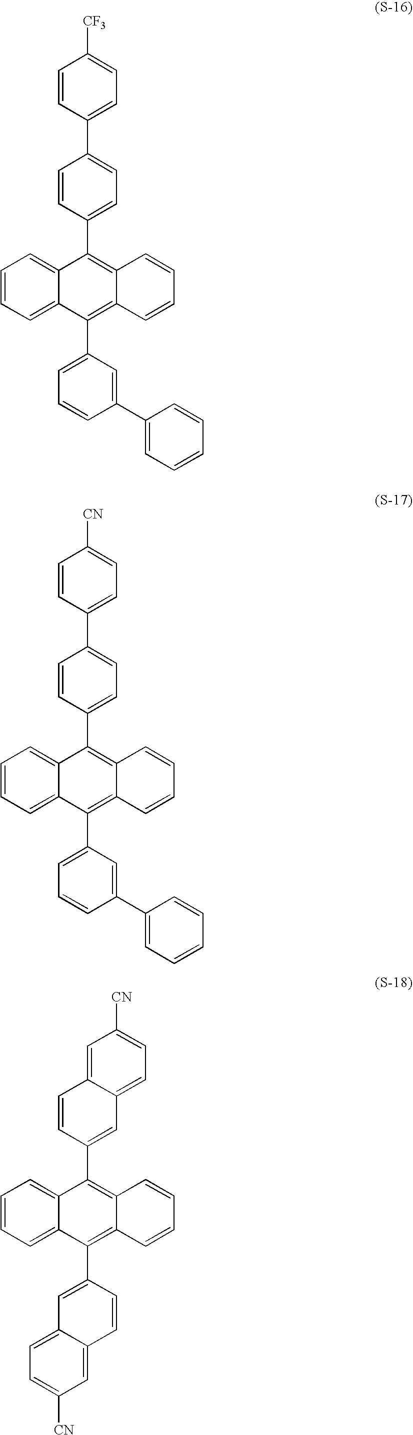

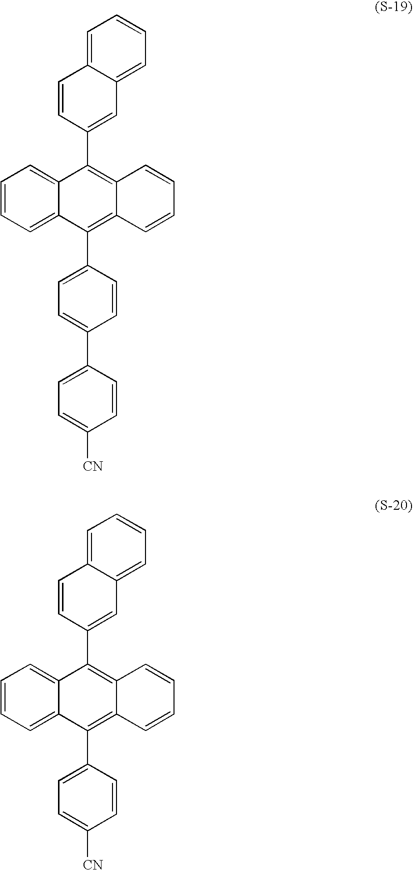

The thickness of the ETL 170 is in the range of from 2 nm to 200 nm, preferably, in the range of from 5 nm to 150 nm.

### Electron-Injecting Layer (EIL) 180

EIL 180 can be an n-type doped layer containing at least one electron-transporting material as a host (or host material) and at least one n-type dopant (or dopant material). The dopant is capable of reducing the host by charge transfer. The term “n-type doped layer” means that this layer has semiconducting properties after doping, and the electrical current through this layer is substantially carried by the electrons.

The host in EIL 180 is an electron-transporting material capable of supporting electron injection and electron transport. The electron-transporting material can be selected from the electron-transporting materials for use in the ETL region as defined above.

The n-type dopant in the n-type doped EIL 180 is selected from alkali metals, alkali metal compounds, alkaline earth metals, or alkaline earth metal compounds, or combinations thereof. The term “metal compounds” includes organometallic complexes, metal-organic salts, and inorganic salts, oxides and halides. Among the class of metal-containing n-type dopants, Li, Na, K, Rb, Cs, Mg, Ca, Sr, Ba, La, Ce, Sm, Eu, Tb, Dy, or Yb, and their compounds, are particularly useful. The materials used as the n-type dopants in the n-type doped EIL 180 also include organic reducing agents with strong electron-donating properties. By “strong electron-donating properties” it is meant that the organic dopant should be able to donate at least some electronic charge to the host to form a charge-transfer complex with the host. Nonlimiting examples of organic molecules include bis(ethylenedithio)-tetrathiafulvalene (BEDT-TTF), tetrathiafulvalene (TTF), and their derivatives. In the case of polymeric hosts, the dopant is any of the above or also a material molecularly dispersed or copolymerized with the host as a minor component. Preferably, the n-type dopant in the n-type doped EIL 180 includes Li, Na, K, Rb, Cs, Mg, Ca, Sr, Ba, La, Ce, Nd, Sm, Eu, Th, Dy, or Yb, or combinations thereof. The n-type doped concentration is preferably in the range of 0.01-20% by volume of this layer. The thickness of the n-type doped EIL 180 is typically less than 200 nm, and preferably in the range of less than 150 nm.

EIL 180 can also include alkaline metal complexes or alkaline earth metal complexes. Wherein, the metal complex in the electron-injecting layer includes a cyclometallated complex represented by Formula (T)

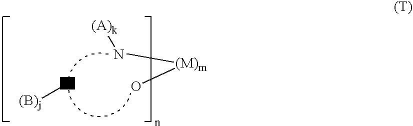

wherein:

Z and the dashed arc represent two or three atoms and the bonds necessary to complete a 5- or 6-membered ring with M;

each A represents H or a substituent and each B represents an independently selected substituent on the Z atoms, provided that two or more substituents can combine to form a fused ring or a fused ring system;

j is 0-3 and k is 1 or 2;

M represents an alkali metal or an alkaline earth metal; and

m and n are independently selected integers selected to provide a neutral charge on the complex.

Illustrative examples of useful electron-injecting materials include, but are not limited to, the following:

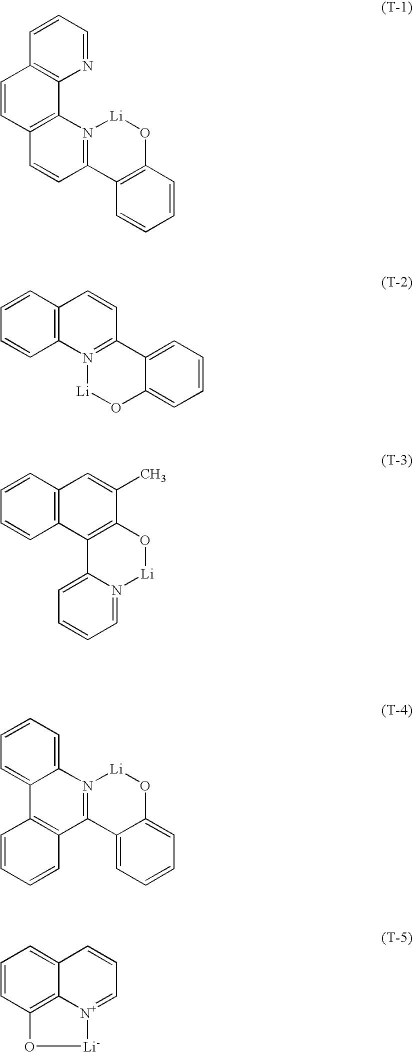

The thickness of EIL is typically less than 100 nm, and preferably in the range of less than 20 nm. If the EIL 180 includes the alkaline metal complexes or alkaline earth metal complexes, its thickness is typically less than 50 nm, and preferably in the range of less than 5 nm.

### Cathode 190

When light emission is viewed solely through the anode 110, the cathode 190 includes nearly any conductive material. Desirable materials have effective film-forming properties to ensure effective contact with the underlying organic layer, promote electron injection at low voltage, and have effective stability. Useful cathode materials often contain a low work function metal (<4.0 eV) or metal alloy. One preferred cathode material includes a Mg:Ag alloy as described in U.S. Pat. No. 4,885,221. Another suitable class of cathode materials includes bilayers including a thin inorganic EIL in contact with an organic layer (e.g., organic EIL or ETL), which is capped with a thicker layer of a conductive metal. Here, the inorganic EIL preferably includes a low work function metal or metal salt and, if so, the thicker capping layer does not need to have a low work function. One such cathode includes a thin layer of LiF followed by a thicker layer of A1 as described in U.S. Pat. No. 5,677,572. Other useful cathode material sets include, but are not limited to, those disclosed in U.S. Pat. No. 5,059,861, U.S. Pat. No. 5,059,862, and U.S. Pat. No. 6,140,763.

When light emission is viewed through the cathode, cathode 190 should be transparent or nearly transparent. For such applications, metals should be thin or one should use transparent conductive oxides, or include these materials. Optically transparent cathodes have been described in more detail in U.S. Pat. No. 4,885,211, U.S. Pat. No. 5,247,190, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, U.S. Pat. No. 6,278,236, U.S. Pat. No. 6,284,393, and EP 1 076 368. Cathode materials are typically deposited by thermal evaporation, electron beam evaporation, ion sputtering, or chemical vapor deposition. When needed, patterning is achieved through many well known methods including, but not limited to, through-mask deposition, integral shadow masking, for example as described in U.S. Pat. No. 5,276,380 and EP 0 732 868, laser ablation, and selective chemical vapor deposition.

### Other Useful Organic Layers

In some instances, a hole-blocking layer (HBL) can be disposed between LEL 150 and ETL 170. The hole-blocking layer includes an electron-transporting material having a HOMO level at least 0.2 eV lower than that of the host in the LEL 150. In other words, applying a HBL adjacent to the LEL can create a hole escape barrier at the interface between the LEL and the HBL. Similarly, an electron-blocking layer (EBL) or an exciton-blocking layer (XBL) can be disposed between HTL 130 and LEL 150 to create an electron escape barrier or an exciton escape barrier at the interface between the EBL (XBL) and the LEL. In some instances, layers 150 or 170 can optionally be collapsed with an adjacent layer into a single layer that serves the function of supporting both light emission and electron transportation. It also known in the art multiple materials can be added to one or more layers in order to create a white emitting OLED, for example, by combining blue- and yellow emitting materials, cyan- and red emitting materials, or red-, green-, and blue emitting materials. White emitting devices are described, for example, in EP 1 187 235, US 20020025419, EP 1 182 244, U.S. Pat. No. 5,683,823, U.S. Pat. No. 5,503,910, U.S. Pat. No. 5,405,709, and U.S. Pat. No. 5,283,182 and can be equipped with a suitable filter arrangement to produce a color emission.

### Substrate

The phosphorescent OLED is typically provided over a supporting substrate where either the anode 110 or cathode 190 can be in contact with the substrate. The electrode in contact with the substrate is conveniently referred to as the bottom electrode. Conventionally, the bottom electrode is the anode 110, but this invention is not limited to that configuration. The substrate can either be light transmissive or opaque, depending on the intended direction of light emission. The light transmissive property is desirable for viewing the EL emission through the substrate. Transparent glass or plastic is commonly employed in such cases. The substrate can be a complex structure comprising multiple layers of materials. This is typically the case for active matrix substrates wherein TFTs are provided below the OLED layers. It is still necessary that the substrate, at least in the emissive pixelated areas, be comprised of largely transparent materials such as glass or polymers. For applications where the EL emission is viewed through the top electrode, the transmissive characteristic of the bottom support is immaterial, and therefore the substrate can be light transmissive, light absorbing or light reflective. Substrates for use in this case include, but are not limited to, glass, plastic, semiconductor materials such as silicon, ceramics, and circuit board materials. Again, the substrate can be a complex structure comprising multiple layers of materials such as found in active matrix TFT designs. It is necessary to provide in these device configurations a light-transparent top electrode.

### Deposition of Organic Layers

The organic materials mentioned above are suitably deposited by any way suitable for the form of the organic materials. In the case of small molecules, they are conveniently deposited through sublimation or evaporation, but can be deposited by other ways such as coating from a solvent together with an optional binder to improve film formation. If the material is a polymer, solvent deposition is usually preferred. The material to be deposited by sublimation or evaporation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. No. 5,688,551, U.S. Pat. No. 5,851,709 and U.S. Pat. No. 6,066,357) or an inkjet method (U.S. Pat. No. 6,066,357).

### Optical Optimization

OLED devices of this invention can employ various well-known optical effects in order to enhance their emissive properties if desired. This includes optimizing layer thicknesses to yield maximum light transmission, providing dielectric mirror structures, replacing reflective electrodes with light-absorbing electrodes, providing anti-glare or anti-reflection coatings over the display, providing a polarizing medium over the display, or providing colored, neutral density, or color-conversion filters over the display. Filters, polarizers, and anti-glare or anti-reflection coatings can be specifically provided over the EL device or as part of the EL device.

### Encapsulation

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOₓ, Teflon, and alternating inorganic/polymeric layers are known in the art for encapsulation. Any of these methods of sealing or encapsulation and desiccation can be used with the EL devices constructed according to the present invention.

This invention is particularly suitable for use in a tandem OLED device since low voltage rise and long lifetime are critical in such applications. A tandem OLED device has a single anode and electrode and contains at least two light-emitting units with an intermediate connector unit between them. The individual light-emitting units in a tandem OLED can emit the same or different color light. Preferably, the tandem OLED produces substantially white light.

The aforementioned OLEDs prepared in accordance with the present invention are useful for various display applications. OLED displays or the other electronic devices can include a plurality of the OLEDs as described above.

### EXAMPLES

The following examples are presented for a further understanding of the present invention. The reduction potential and the oxidation potential of the materials were measured using a Model CHI660 electrochemical analyzer (CH Instruments, Inc., Austin, Tex.) with the method as discussed before. During the fabrication of OLEDs, the thickness of the organic layers and the doping concentrations were controlled and measured in situ using calibrated thickness monitors built in an evaporation system (Made by Trovato Mfg., Inc., Fairport, N.Y.). The EL characteristics of all the fabricated devices were evaluated using a constant current source (KEITHLEY 2400 SourceMeter, made by Keithley Instruments, Inc., Cleveland, Ohio) and a photometer (PHOTO RESEARCH SpectraScan PR 650, made by Photo Research, Inc., Chatsworth, Calif.) at room temperature. Operational lifetime (or stability) of the devices was tested at room temperature and at an initial luminance of 1,000 cd/m² or at 80 mA/cm² by driving a constant current through the devices. The color was reported using Commission Internationale de I'Eclairage (CIE) coordinates.

### Example 1 (Comparative)

The preparation of a conventional OLED (Device 1) is as follows: A 1.1 mm thick glass substrate coated with a transparent ITO conductive layer was cleaned and dried using a commercial glass scrubber tool. The thickness of ITO is about 22 nm and the sheet resistance of the ITO is about 68 Ω/square. The ITO surface was subsequently treated with oxidative plasma to condition the surface as an anode. A layer of CFₓ, 1 nm thick, was deposited on the clean ITO surface as the anode buffer layer by decomposing CHF₃ gas in an RF plasma treatment chamber. The substrate was then transferred into a vacuum deposition chamber for deposition of all other layers on top of the substrate. The following layers were deposited in the following sequence by evaporation from a heated boat under a vacuum of approximately 10⁻⁶ Torr:

a) an HTL, 75 nm thick, including N,N′-di-1-naphthyl-N,N′-diphenyl-4,4′-diaminobiphenyl (NPB);

b) a LEL, 30 nm thick, including tris(8-hydroxyquinoline)aluminum(III) (Alq) doped with about 1.0% by volume of 10-(2-benzothiazolyl)-1,1,7,7-tetramethyl-2,3,6,7-tetrahydro-1H,5H,11H(1)benzopyrano(6,7,8-ij)quinolizin-11-one (C545T);

c) an ETL, 30 nm thick, including Alq doped with 1.5% by volume of Li; and

d) a cathode: approximately 210 nm thick, including Mg doped with 5% by volume of Ag (MgAg).

After the deposition of these layers, the device was transferred from the deposition chamber into a dry box (made by VAC Vacuum Atmosphere Company, Hawthorne, Calif.) for encapsulation. The OLED has an emission area of 10 mm².

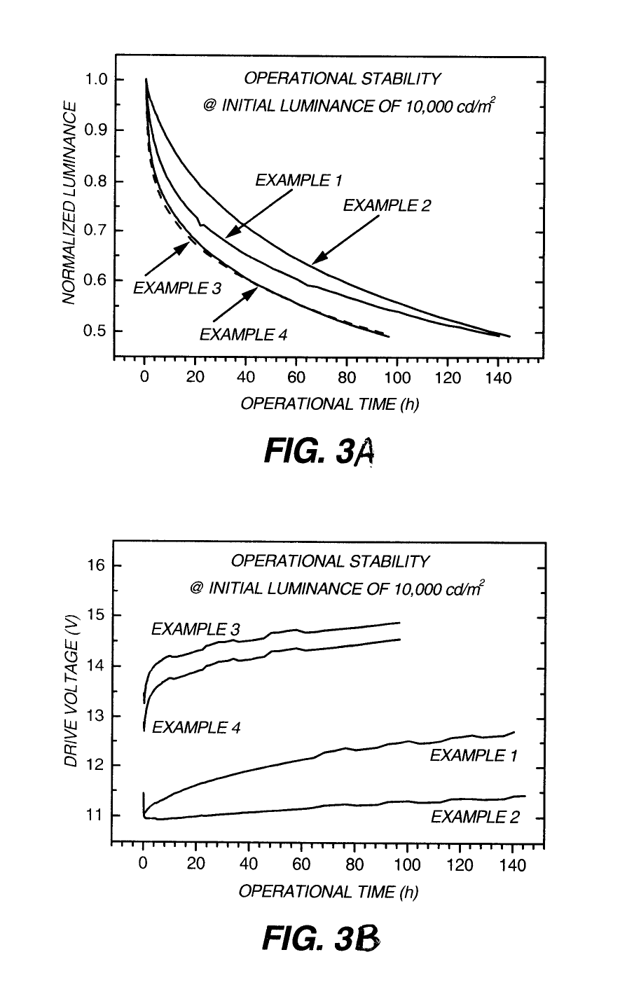

Device 1 is denoted as: ITO/75 nm NPB/30 nm Alq:1.0% C545T/30 nm Alq:1.5% Li/210 nm MgAg. The EL performance of the device is summarized in Table 3, and its operational stability is shown in FIGS. 3A and 3B.

### Example 2 (Inventive)

Another OLED (Device 2) which is fabricated with the same method and the same layer structure as Example 1, except that an HIL is inserted between the modified ITO anode and the HTL. The layer structure is:

a) an HIL, 55 nm thick, including hexaazatriphenylene hexacarbonitrile (HAT-CN) doped with 5% by volume of 4,4′,4″-tris[(3-ethylphenyl)phenylamino]triphenylamine (m-TDATA), wherein the reduction potential of HAT-CN is −0.08 V vs. SCE (greater than −0.1 V vs. SCE) and the oxidation potential of m-TDATA is 0.46 V (less than 1.0 V vs. SCE);

b) a HTL, 20 nm thick, including NPB;

c) a LEL, 30 nm thick, including Alq doped with 1.0% by volume of C545T;

d) an ETL, 30 nm thick, including Alq doped with 1.5% by volume of Li, which is also considered as an EIL; and

e) a cathode: approximately 210 nm thick, including MgAg.

Device 2 is denoted as: ITO/55 nm (HAT-CN):5%(m-TDATA)/20 nm NPB/30 nm Alq:1.0% C545T/30 nm Alq:1.5% Li/210 nm MgAg. The EL performance of the device is summarized in Table 3, and its operational stability is shown in FIGS. 3A and 3B.

### Example 3 (Comparative)

Another OLED (Device 3) is fabricated with the same method and the same layer structure as Example 2, except that the HIL and the ETL are different. The layer structure is:

a) an HIL, 55 nm thick, m-TDATA;

b) a HTL, 20 nm thick, including NPB;

c) an LEL, 30 nm thick, including Alq doped with 1.0% by volume of C545T;

d) an ETL, 30 nm thick, including Alq; and

e) a cathode: approximately 210 nm thick, including MgAg.

Device 3 is denoted as: ITO/55 nm (m-TDATA)/20 nm NPB/30 nm Alq:1.0% C545T/30 nm Alq/210 nm MgAg. The EL performance of the device is summarized in Table 3, and its operational stability is shown in FIGS. 3A and 3B.

### Example 4 (Comparative)

Another OLED (Device 4) is fabricated with the same method and the same layer structure as Example 2, except that the HIL and the ETL is different. The layer structure is:

a) an HIL, 55 nm thick, including m-TDATA doped with 5% by volume of HAT-CN, wherein the oxidation potential of m-TDATA is 0.46 V vs. SCE and the reduction potential of HAT-CN is −0.08 V vs. SCE;

b) an HTL, 20 nm thick, including NPB;

c) an LEL, 30 nm thick, including Alq doped with 1.0% by volume of C545T;

d) an ETL, 30 nm thick, including Alq; and

e) a cathode: approximately 210 nm thick, including MgAg.

Device 4 is denoted as: ITO/55 nm (m-TDATA):5%(HAT-CN)/20

TABLE 3

| Example (EL | | | | | | | | |
|---|---|---|---|---|---|---|---|---|
| measured @ | | | Luminous | | | Power | T₅₀ @ | Vrise |
| RT and | Voltage | Luminance | Efficiency | CIE x | CIE y | Efficiency | 10,000 cd/m² | @ T₅₀ |
| 20 mA/cm²) | (V) | (cd/m²) | (cd/A) | (1931) | (1931) | (lm/W) | (h) | (V) |
| (Comparative) | 5.0 | 2084 | 10.4 | 0.290 | 0.651 | 6.5 | 134 | 1.7 |
| 2 (Inventive) | 4.8 | 2033 | 10.2 | 0.297 | 0.647 | 6.8 | 139 | 0.5 |
| 3 (Comparative) | 9.1 | 3313 | 16.6 | 0.294 | 0.651 | 5.7 | 93 | 1.4 |
| 4 (Comparative) | 8.5 | 3259 | 16.3 | 0.294 | 0.651 | 6.0 | 91 | 1.6 |

nm NPB/30 nm Alq:1.0% C545T/30 nm Alq/210 nm MgAg. The EL performance of the device is summerized in Table 3, and its operational stability is shown in FIGS. 3a and 3B

In the above examples, Example 1 is a conventional OLED and Example 2 is an inventive OLED. The largest difference between Device 1 and Device 2 is the voltage rise to arrive at T₅₀. The rate of voltage rise in Device 1 is about 12.7 mV/hour at an initial luminance of 10,000 cd/m², while that in Device 2 is about 3.6 mV/hour. The low voltage rise is useful for device applications. Therefore, adding an m-TDATA doped HAT-CN layer as an HIL in accordance with the present invention can substantially improve the voltage stability. This can also increase the operational lifetime when the device is driven with a constant voltage drive scheme.

When a substantially pure m-TDATA is used as an HIL as in Device 3, the luminous efficiency is increased compared to Device 1, however the power efficiency is reduced due to a high drive voltage. The operational lifetime of Device 3 is also reduced. Moreover, the rate of voltage rise to arrive at T₅₀ in Device 3 is about 15.1 mV/hour which is higher than that in Device 1. When a HAT-CN doped m-TDATA layer is used as an HIL as in Device 4, there is an improvement regarding drive voltage and power efficiency, however there is basically no improvement regarding operational lifetime and the voltage rise (17.6 mV/hour).

The HIL in both Device 2 and Device 4 contains both HAT-CN and m-TDATA. HAT-CN is used as the first material at higher volume ratio and m-TDATA is used as the second material in lower volume ratio in Inventive Device 2, while HAT-CN is used at a lower volume ratio and m-TDATA is used at a higher volume ratio in Device 4. It is obvious that Device 2 fabricated in accordance with the present invention has lower drive voltage, higher power efficiency, longer operational lifetime, and a lower voltage rise to arrive at T₅₀.

### Example 5 (Comparative)

Another OLED (Device 5) is fabricated with the same method and the same layer structure as Example 2, except that the HIL is different. The layer structure is:

a) an HIL, 10 nm thick, including HAT-CN;

b) a HTL, 65 nm thick, including NPB;

c) an LEL, 30 nm thick, including Alq doped with 1.0% by volume of C545T;

d) an ETL, 30 nm thick, including Alq doped with 1.2% by volume of Li, which is also considered as an EIL; and

e) a cathode: approximately 210 nm thick, including MgAg.

Device 5 is denoted as: ITO/10 nm (HAT-CN)/65 nm NPB/30 nm Alq: 1.0% C545T/30 nm Alq: 1.2% Li/210 nm MgAg. The EL performance of the device is summarized in Table 4.

### Example 6 (Comparative)

Another OLED (Device 6) is fabricated with the same method and the same layer structure as Example 5, except that the thickness of the HIL is different. The layer structure is:

a) an HIL, 55 nm thick, including HAT-CN;

b) an HTL, 20 nm thick, including NPB;

c) an LEL, 30 nm thick, including Alq doped with 1.0% by volume of C545T;

d) an ETL, 30 nm thick, including Alq doped with 1.2% by volume of Li, which is also considered as an EIL; and

e) a cathode: approximately 210 nm thick, including MgAg.

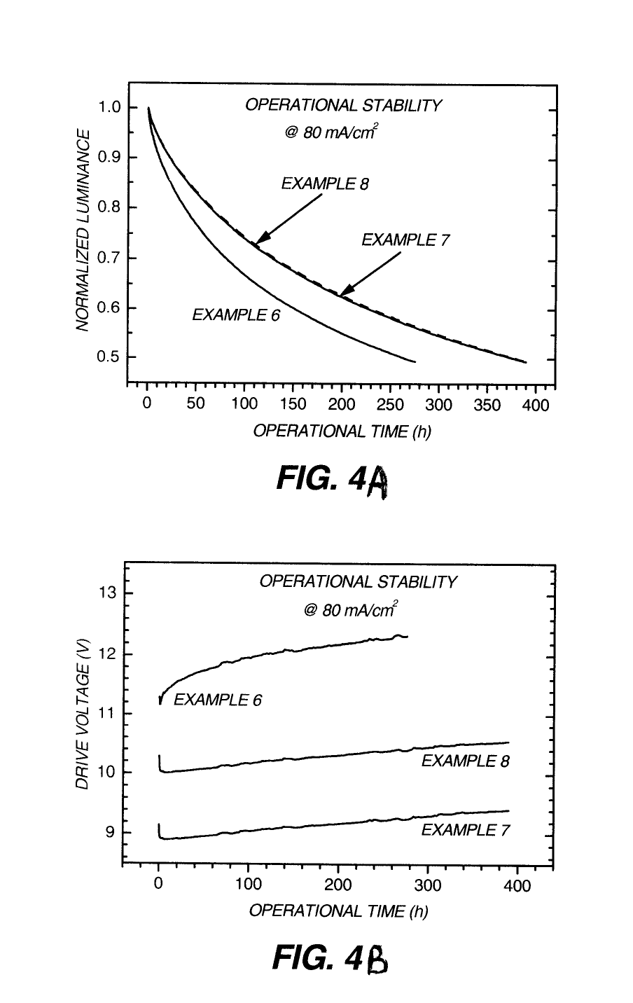

Device 6 is denoted as: ITO/55 nm (HAT-CN)/20 nm NPB/30 nm Alq:1.0% C545T/30 nm Alq:1.2% Li/210 nm MgAg. The EL performance of the device is summarized in Table 4, and its operational stability is shown in FIGS. 4A and 4B.

### Example 7 (Inventive)

An inventive OLED (Device 7) is fabricated with the same method and the same layer structure as Example 6, except that the HIL includes a first material and a second material. The layer structure is:

a) an HIL, 55 nm thick, including HAT-CN doped with 5% by volume of Formula Inv-1, wherein the reduction potential of HAT-CN is −0.08 V vs. SCE (greater than −0.1 V vs. SCE) and the oxidation potential of Formula Inv-1 is 0.68 V (less than 1.0 V vs. SCE);

b) a HTL, 20 nm thick, including NPB;

c) a LEL, 30 nm thick, including Alq doped with 1.0% by volume of C545T;

d) an ETL, 30 nm thick, including Alq doped with 1.2% by volume of Li, which is also considered as an EIL; and

e) a cathode: approximately 210 nm thick, including MgAg.

Device 7 is denoted as: ITO/55 nm (HAT-CN):5% (Formula Inv-1)/20 nm NPB/30 nm Alq:1.0% C545T/30 nm Alq:1.2% Li/210 m MgAg. The EL performance of the device is summarized in Table 4, and its operational stability is shown in FIGS. 4A and 4B.

### Example 8 (Inventive)

An inventive OLED (Device 8) is fabricated with the same method and the same layer structure as Example 7, except that the thickness of HIL is increased. The layer structure is:

a) an HIL, 130 nm thick, including HAT-CN doped with 5% by volume of Formula Inv-1;

b) an HTL, 20 nm thick, including NPB;

c) an LEL, 30 nm thick, including Alq doped with 1.0% by volume of C545T;

d) an ETL, 30 nm thick, including Alq doped with 1.2% by volume of Li, which is also considered as an EIL; and

e) a cathode: approximately 210 nm thick, including MgAg.

Device 8 is denoted as: ITO/130 nm (HAT-CN):5% (Formula Inv-1)/20 nm NPB/30 nm Alq:1.0% C545T/30 nm Alq:1.2% Li/210 nm MgAg. The EL performance of the device is summarized in Table 4, and its operational stability is shown in FIGS. 4A and 4B.

### Example 9 (Inventive)

An inventive OLED (Device 9) is fabricated with the same method and the same layer structure as Example 8, except that the concentration of the second material in the HIL is increased. The layer structure is:

a) an HIL, 130 nm thick, including HAT-CN doped with 10% by volume of Formula Inv-1;

b) an HTL, 20 nm thick, including NPB;

c) an LEL, 30 nm thick, including Alq doped with 1.0% by volume of C545T;

d) an ETL, 30 nm thick, including Alq doped with 1.2% by volume of Li, which is also considered as an EIL; and

e) a cathode: approximately 210 nm thick, including MgAg.

Device 9 is denoted as: ITO/130 nm (HAT-CN):10% (Formula Inv-1)/20 nm NPB/30 nm Alq:1.0% C545T/30 nm Alq:1.2% Li/210 nm MgAg. The EL performance of the device is summarized in Table 4.

TABLE 4

| Example | | | | | | | | |
|---|---|---|---|---|---|---|---|---|
| (EL measured @ | | | Luminous | | | Power | T₅₀ @ | Vrise |
| RT and | Voltage | Luminance | Efficiency | CIE x | CIE y | Efficiency | 80 mA/cm² | @ T₅₀ |
| 20 mA/cm²) | (V) | (cd/m²) | (cd/A) | (1931) | (1931) | (lm/W) | (h) | (V) |
| 5 (Comparative) | 5.0 | 1902 | 9.5 | 0.285 | 0.648 | 6.0 | 361 | 0.5 |
| 6 (Comparative) | 5.8 | 2215 | 11.1 | 0.290 | 0.645 | 6.0 | 266 | 1.2 |
| 7 (Inventive) | 4.6 | 1846 | 9.2 | 0.288 | 0.646 | 6.3 | 379 | 0.5 |
| 8 (Inventive) | 4.9 | 2263 | 11.3 | 0.292 | 0.649 | 7.2 | 384 | ~0.5 |
| 9 (Inventive) | 4.7 | 2245 | 11.2 | 0.297 | 0.646 | 7.5 | 374 | ~0.5 |

In the above examples, Device 5 is a reference having only a single HIL material having low drive voltage, long operational lifetime, and low voltage rise (1.4 mV/hour). However, with a thicker HIL as in Device 6, the voltage is increased, the operational life time at 80 mA/cm² is decreased, and the rate of voltage rise to arrive at T₅₀ is increased to 4.5 mV/hour. Moreover, it was found that greater than 20% of the emission area is filled with dark spots, and the actual luminous efficiency and power efficiency are in reality lower than the measured data shown in Table 2. Therefore, Device 6 which has a thicker HAT-CN layer as the HIL is not useful for practical applications.

However, when the material of Formula Inv-1 is added to the HIL along with the HAT-CN, the voltage is reduced, even in Devices 8 and 9 with 130 nm thick HIL's; the power efficiency is increased, the operational lifetime is improved and there is a low voltage rise. Therefore, the data for Devices 7-9 indicate that having a HIL with two materials of the appropriate redox potentials in accordance with the present invention can indeed improve the OLED performance.

In the following three examples, it was shown why any material with an oxidation potential higher than 0.7 V, such as NPB (with an oxidation potential of 0.85 V), was not used as a second material in the HIL.

### Example 10 (Comparative)

An OLED (Device 10) is fabricated with the same method as Example 1. The layer structure is:

a) an HTL, 75 nm thick, including NPB;

b) an LEL, 20 nm thick, including Formula S-10 doped with 7.0% by volume of Formula J48;

c) an ETL, 35 nm thick, including Formula L-2 doped with 1.0% by volume of Li, which is also considered as an EIL; and

d) a cathode: approximately 100 nm thick, including Al.

Device 10 is denoted as: ITO/75 nm NPB/35 nm (Formula S-10):7.0% (Formula J48)/35 nm (Formula L-2):1.0% Li/100 nm Al. The EL performance of the device is summarized in Table 5.

### Example 11 (Comparative)

An OLED (Device 11) is fabricated with the same method as Example 1. The layer structure is:

a) an HIL, 55 nm thick, including HAT-CN;

b) an HTL, 20 nm thick, including NPB;

c) an LEL, 20 nm thick, including Formula S-10 doped with 7.0% by volume of Formula J48;

d) an ETL, 35 nm thick, including Formula L-2 doped with 1.0% by volume of Li, which is also considered as an EIL; and

e) a cathode: approximately 100 nm thick, including A1.

Device 11 is denoted as: ITO/55 nm (HAT-CN)/20 nm NPB/35 nm (Formula S-10):7.0% (Formula J48)/35 nm (Formula L-2):1.0% Li/100 nm Al. The EL performance of the device is summarized in Table 5.

### Example 12 (Comparative)

An OLED (Device 12) is fabricated with the same method as Example 1. The layer structure is:

a) an HIL, 55 nm thick, including HAT-CN doped with 15% by volume of NPB;

b) an HTL, 20 nm thick, including NPB;

c) an LEL, 20 nm thick, including Formula S-10 doped with 7.0% by volume of Formula J48;

d) an ETL, 35 nm thick, including Formula L-2 doped with 1.0% by volume of Li, which is also considered as an EIL; and

e) a cathode: approximately 100 nm thick, including A1.

Device 12 is denoted as: ITO/55 nm (HAT-CN):15% NPB/20 nm NPB/35 nm (Formula S-10):7.0% (Formula J48)/35 nm (Formula L-2):1.0% Li/100 nm A1. The EL performance of the device is summarized in Table 5.

TABLE 5

| Example | | | | | | | | |
|---|---|---|---|---|---|---|---|---|
| (EL measured @ | | | Luminous | | | Power | T₅₀ @ | Vrise |
| RT and | Voltage | Luminance | Efficiency | CIE x | CIE y | Efficiency | 5,000 cd/m² | @ T₅₀ |
| 20 mA/cm²) | (V) | (cd/m²) | (cd/A) | (1931) | (1931) | (lm/W) | (h) | (V) |
| 10 | 3.4 | 742 | 3.71 | 0.145 | 0.172 | 3.4 | 114 | >1.2 |
| (Comparative) | | | | | | | | |
| 11 | 4.3 | 663 | 3.31 | 0.145 | 0.175 | 2.4 | 81 | ~0.2 |
| (Comparative) | | | | | | | | |
| 12 | 5.7 | 808 | 4.0 | 0.145 | 0.171 | 2.3 | 30 | ~0.2 |
| (Comparative) | | | | | | | | |

The data shown in Table 5 indicate that there is no benefit to use thick HAT-CN layer (˜55 nm) or NPB-doped HAT-CN layer (55 nm) as an HIL in OLEDs, because the drive voltage is increased, the power efficiency is reduced, and especially the operational lifetime is shortened comparing to the conventional OLED structure (Example 10).

The invention has been described in detail with particular reference to certain preferred embodiments thereof, but it will be understood that variations and modifications can be effected within the spirit and scope of the invention.

### Parts List

100 OLED of the present invention
110 anode
120 hole-injecting layer (HIL)
130 hole-transporting layer (HTL)
150 light-emitting layer (LEL)
170 electron-transporting layer (ETL)
180 electron-injecting layer (EIL)
190 cathode
200 OLED of the present invention

1. An OLED comprising:
a) an anode;
b) a cathode;
c) a hole-injecting layer disposed over the anode, wherein the hole-injecting layer includes a first organic material with a reduction potential greater than −0.1 V and a lesser amount by volume of a second material with an oxidation potential less than 0.7 V, and wherein the second material does not include metal complexes;
d) a hole-transporting layer disposed over the hole-injecting layer;
e) a light-emitting layer disposed between the hole-transporting layer and the cathode; and
f) an electron-transporting layer disposed between the light-emitting layer and the cathode.

2. The OLED of claim 1 wherein the hole-injecting layer contains more than 60% by volume of the first organic material and contains less than 40% by volume of the second material.

3. The OLED of claim 2 wherein the hole-injecting layer contains more than 70% by volume of the first organic material and contains less than 30% by volume of the second material.

4. The OLED of claim 1 wherein the hole-injecting layer has a thickness in a range of from 0.1 to 150 nm.

5. The OLED of claim 4 wherein the hole-injecting layer has a thickness in a range of from 1 to 50 nm.

6. The OLED of claim 1 wherein the first organic material in the hole-injecting layer is selected from: 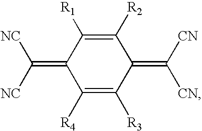
wherein R₁-R₄ independently represents hydrogen, fluorine, or substituents independently selected from nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, or substituted or unsubstituted alkyl, where R and R′ include substituted or unsubstituted alkyl or aryl; or wherein R₁ and R₂, or R₃ and R₄, combine form a ring structure including an aromatic ring, a heteroaromatic ring, or a non-aromatic ring, and each ring is substituted or unsubstituted.

7. The OLED of claim 6 wherein the first organic material in the hole-injecting layer is selected from:

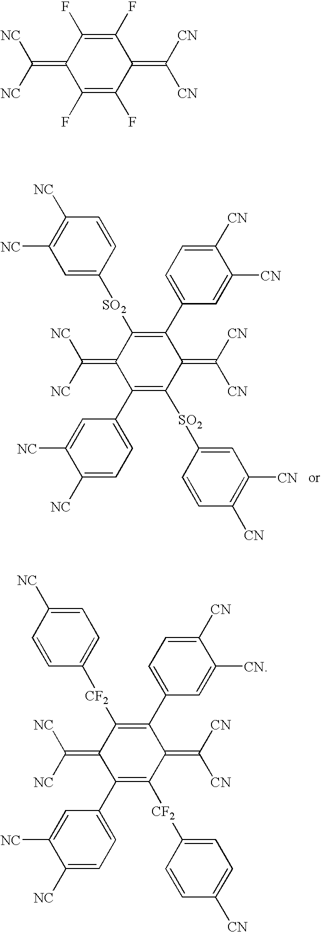

8. The OLED of claim 1 wherein the first organic material in the hole-injecting layer is selected from: 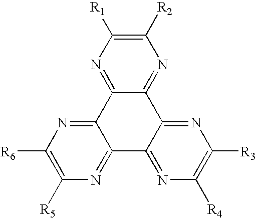
wherein R₁-R₆ represent hydrogen or a substituent independently selected from halo, nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, or substituted or unsubstituted alkyl, where R and R′ include substituted or unsubstituted alkyl or aryl; or wherein R₁ and R₂, R₃ and R₄, or R₅ and R₆, combine form a ring structure including an aromatic ring, a heteroaromatic ring, or a non-aromatic ring, and each ring is substituted or unsubstituted.

9. The OLED of claim 8 wherein the first organic material in the hole-injecting layer is selected from:

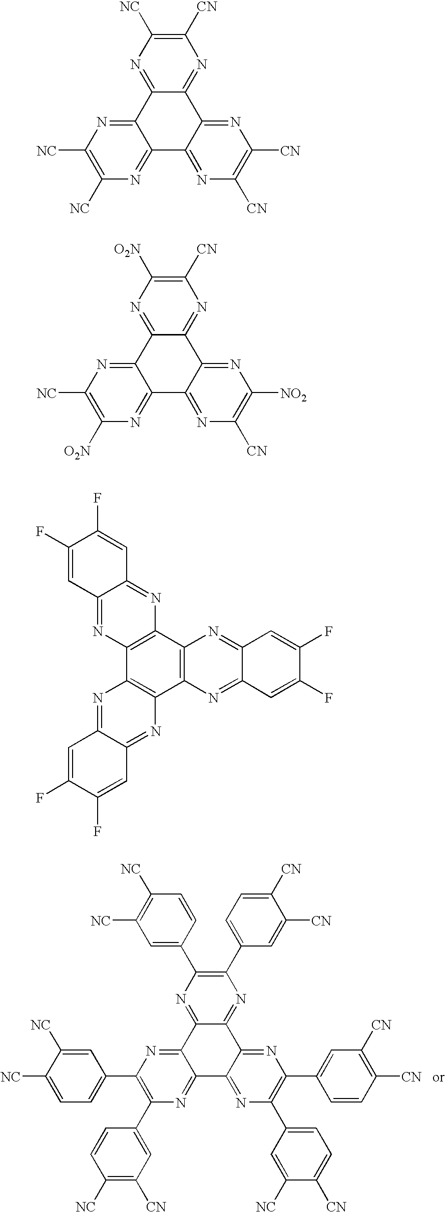

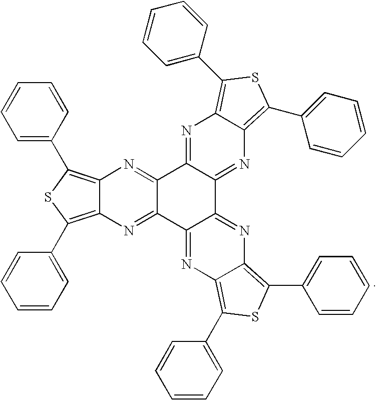

10. The OLED of claim 1 wherein the second material in the hole-injecting layer is a 2,6-diamino-substituted anthracene compound having an oxidation potential less than 0.7 V.

11. The OLED of claim 10 wherein the 2,6-diamino-substituted anthracene compound is according to the formula IV: 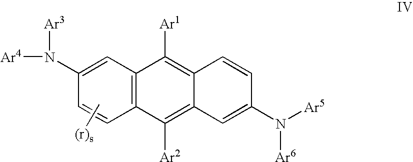
wherein
Ar³-Ar⁶ are independently selected aromatic groups and can be the same or different and provided that two groups on the same nitrogen can combine to form a ring;
Ar¹ and Ar² can be the same or different and each represents an independently selected aromatic group or N(Ar⁷)(Ar⁷), wherein each Ar⁷ can be the same or different and each represents an independently selected aromatic group;
r represents an independently selected substituent, provided two adjacent r groups can combine to form a fused ring; and
s is 0-3.

12. The OLED of claim 11 wherein the 2,6-diamino-substituted anthracene compound is selected from:

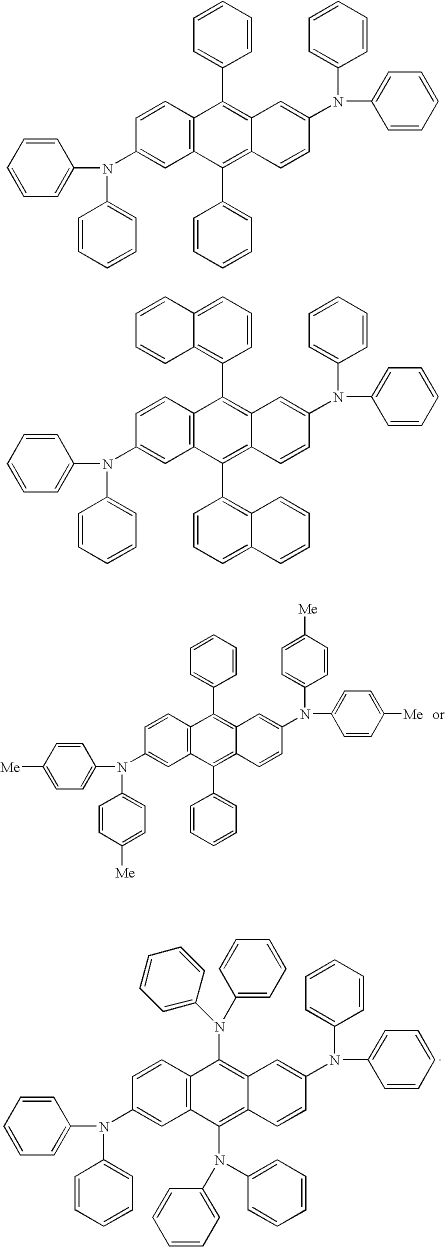

13. The OLED of claim 1 wherein the second material in the hole-injecting layer includes a dihydrophenazine compound having an oxidation potential less than 0.7 V.

14. The OLED of claim 13 wherein the dihydrophenazine compound is according to the formula: 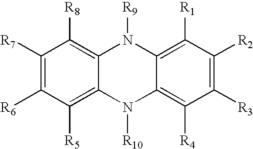
wherein:
R₁ represents hydrogen or an independently selected substituentand can be connected to R₂ to form a 5 or 6 member ring system;
R₄ represents hydrogen or an independently selected substituent and can be connected to R₃ to form a 5 or 6 member ring system;
R₅ represents hydrogen or an independently selected substituent and can be connected to R₆ to form a 5 or 6 member ring system;
R₈ represents hydrogen or an independently selected substituent and can be connected to R₇ to form a 5 or 6 member ring system;
R₂ and R₃ individually represent hydrogen or an independently selected substituent and can be connected to form a 5 or 6 member ring system;
R₆ and R₇ individually represent hydrogen or an independently selected substituent and can be connected to form a 5 or 6 member ring system; and
R₉ and R₁₀ represent hydrogen or an independently selected substituent.

15. The OLED of claim 14 wherein the dihydrophenazine compound is selected from:

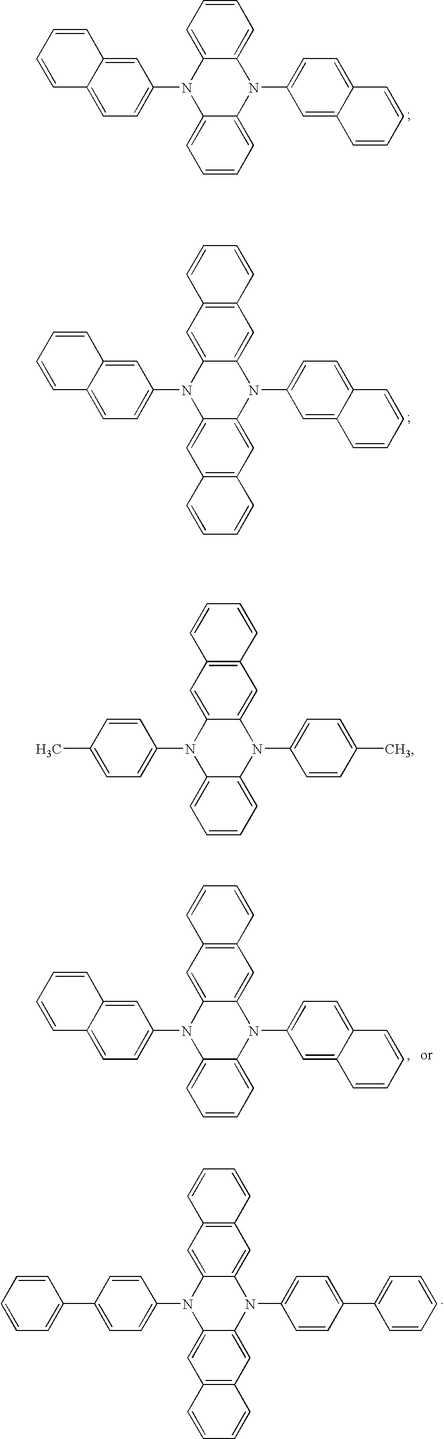

16. The OLED of claim 1 wherein the second material in the hole-injecting layer includes an aromatic tertiary amine compound having an oxidation potential less than 0.7 V.

17. The OLED of claim 16 wherein the aromatic tertiary amine compound includes 4,4′,4″-tris[(3-methylphenyl)phenylamino]triphenylamine.

18. The OLED of claim 1 wherein the OLED emits light with different colors including white color.

19. The OLED of claim 1 wherein the OLED includes tandem OLED structures.
